(19) United States
(12) Patent Application Publication
(10) Pub. No.: US 2025/0040367 A1
(43) Pub. Date: Jan. 30, 2025

(54) DISPLAY SUBSTRATE AND DISPLAY APPARATUS

(71) Applicant: BOE Technology Group Co., Ltd., Beijing (CN)

(72) Inventors: Hao Zhang, Beijing (CN); Pinfan Wang, Beijing (CN)

(73) Assignee: BOE Technology Group Co., Ltd., Beijing (CN)

(21) Appl. No.: 18/264,026

(22) PCT Filed: Nov. 17, 2022
(86) PCT No.: PCT/CN2022/132532

§ 371 Date: Aug. 2, 2023

(51) Int. Cl. H10K 59/131

(52) U.S. Cl. CPC H10K 59/131

(57) ABSTRACT

A display substrate is provided. The display substrate includes a plurality of islands and a plurality of bridges connecting the plurality of islands; wherein the display substrate comprises a first voltage supply network; the first voltage supply network comprises a plurality of first connecting structures in a display area of the display substrate, a first row connecting line, a second row connecting line, a first column connecting line, and a second column connecting line; a respective first connecting structure of the plurality of first connecting structures is connected by the first row connecting line, the second row connecting line, the first column connecting line, and the second column connecting line, to four adjacent first connecting structures, respectively; the first row connecting line, the second row connecting line, the first column connecting line, and the second column connecting line are in four different bridges of the plurality of bridges.

### TECHNICAL FIELD

The present invention relates to display technology, more particularly, to a display substrate and a display apparatus.

### BACKGROUND

Organic Light Emitting Diode (OLED) display is one of the hotspots in the field of flat panel display research today. Unlike Thin Film Transistor-Liquid Crystal Display (TFT-LCD), which uses a stable voltage to control brightness, OLED is driven by a driving current required to be kept constant to control illumination. The OLED display panel includes a plurality of pixel units configured with pixel-driving circuits arranged in multiple rows and columns. Each pixel-driving circuit includes a driving transistor having a gate terminal connected to one gate line per row and a drain terminal connected to one data line per column. When the row in which the pixel unit is gated is turned on, the switching transistor connected to the driving transistor is turned on, and the data voltage is applied from the data line to the driving transistor via the switching transistor, so that the driving transistor outputs a current corresponding to the data voltage to an OLED device. The OLED device is driven to emit light of a corresponding brightness.

### SUMMARY

In one aspect, the present disclosure provides a display substrate, comprising a plurality of islands and a plurality of bridges connecting the plurality of islands; wherein the display substrate comprises a first voltage supply network; the first voltage supply network comprises a plurality of first connecting structures in a display area of the display substrate, a first row connecting line, a second row connecting line, a first column connecting line, and a second column connecting line; a respective first connecting structure of the plurality of first connecting structures is connected by the first row connecting line, the second row connecting line, the first column connecting line, and the second column connecting line, to four adjacent first connecting structures, respectively; the first row connecting line, the second row connecting line, the first column connecting line, and the second column connecting line are in four different bridges of the plurality of bridges.

Optionally, the first row connecting line connects the respective first connecting structure with a first connecting structure in a first adjacent row and in a same column together; the second row connecting line connects the respective first connecting structure with a first connecting structure in a second adjacent row and in a same column together; and the first adjacent row and the second adjacent row are two different rows on two different sides, along a column direction, of a present row having the respective first connecting structure.

Optionally, the first column connecting line connects the respective first connecting structure with a first connecting structure in a first adjacent column and in a same row together; the second column connecting line connects the respective first connecting structure with a first connecting structure in a second adjacent column and in a same row together; and the first adjacent column and the second adjacent column are two different columns on two different sides, along a row direction, of a present column having the respective first connecting structure.

Optionally, the respective first connecting structure comprises a first connecting line and a second connecting line electrically connected to each other; the first connecting line is connected to the first row connecting line and the first column connecting line; and the second connecting line is connected to the second row connecting line and the second column connecting line.

Optionally, the respective first connecting structure further includes one or more connecting lines in a layer different from the first connecting line and the second connecting line.

Optionally, the one or more connecting lines includes a fourth connecting line connecting the first connecting line and the second connecting line together; the first connecting line and the second connecting line are in a conductive layer; and the fourth connecting line is in a signal line layer.

Optionally, the one or more connecting lines includes a cathode connecting line and a cathode connecting pad connecting the first connecting line and the second connecting line together; and at least one of the cathode connecting line and the cathode connecting pad is further connected to a cathode.

Optionally, the display substrate further comprises at least one first voltage supply pad in a peripheral area of the display substrate; a first column of connecting structures directly adjacent to, and connected to, the at least one first voltage supply pad; and a first pad connecting line connecting a respective first column connecting structure in the first column of connecting structures with the at least one first voltage supply pad.

Optionally, the display substrate further comprises at least one first voltage supply pad in a peripheral area of the display substrate; a first row of connecting structures directly adjacent to, and connected to, the at least one first voltage supply pad; and a second pad connecting line connecting a respective first row connecting structure in the first row of connecting structures with the at least one first voltage supply pad.

Optionally, the display substrate further comprises: at least one first voltage supply pad in a peripheral area of the display substrate; a first corner connecting structure directly adjacent to, and connected to, the at least one first voltage supply pad; a third pad connecting line connecting the first corner connecting structure with the at least one first voltage supply pad; and a fourth pad connecting line connecting the first corner connecting structure with the at least one first voltage supply pad.

Optionally, the display substrate further comprises: a second voltage supply network; wherein the second voltage supply network comprises a plurality of second connecting structures in a display area of the display substrate, a third row connecting line, a fourth row connecting line, a third column connecting line, and a fourth column connecting line; a respective second connecting structure of the plurality of second connecting structures is connected by the third row connecting line, the fourth row connecting line, the third column connecting line, and the fourth column connecting line, to four adjacent second connecting structures, respectively; the third row connecting line, the fourth row connecting line, the third column connecting line, and the fourth column connecting line are in the four different bridges.

Optionally, the third row connecting line connects the respective second connecting structure with a second connecting structure in a first adjacent row and in a same column together; the fourth row connecting line connects the respective second connecting structure with a connecting structure in a second adjacent row and in a same column together; the first adjacent row and the second adjacent row are two different rows on two different sides, along a column direction, of a present row having the respective second connecting structure.

Optionally, the third column connecting line connects the respective second connecting structure with a connecting structure in a first adjacent column and in a same row together; the fourth column connecting line connects the respective second connecting structure with a connecting structure in a second adjacent column and in the same row together; and the first adjacent column and the second adjacent column are two different columns on two different sides, along a row direction, of a present column having the respective second connecting structure.

Optionally, the respective second connecting structure comprises a third connecting line in a conductive layer; and the third row connecting line, the fourth row connecting line, the third column connecting line, and the fourth column connecting line are in a signal line layer.

Optionally, the first row connecting line and the third row connecting line are in a same first bridge; the second row connecting line and the fourth row connecting line are in a same second bridge; the first column connecting line and the third column connecting line are in a same third bridge; and the second column connecting line and the fourth column connecting line are in a same fourth bridge.

Optionally, the display substrate further comprises: at least one second voltage supply pad in a peripheral area of the display substrate; a second row of connecting structures directly adjacent to, and connected to, the at least one second voltage supply pad; a fifth pad connecting line connecting a respective second row connecting structure in the second row of connecting structures with the at least one second voltage supply pad; and a sixth pad connecting line connecting a respective second row connecting structure in the second row of connecting structures with the at least one second voltage supply pad.

Optionally, the display substrate further comprises: at least one second voltage supply pad in a peripheral area of the display substrate; a second corner connecting structure directly adjacent to, and connected to, the at least one second voltage supply pad; a seventh pad connecting line connecting the second corner connecting structure with the at least one second voltage supply pad; and an eighth pad connecting line connecting the second corner connecting structure with the at least one second voltage supply pad.

Optionally, the display substrate further comprises at least one first voltage supply pad in a peripheral area of the display substrate; wherein the at least one first voltage supply pad substantially surrounds the display area; and the first voltage supply network is connected to the at least one first voltage supply pad on all sides of the display area.

Optionally, the display substrate further comprises at least one second voltage supply pad in a peripheral area of the display substrate; wherein the at least one second voltage supply pad comprises two portions on two opposite sides of the display area, the two portions configured to receive a second voltage supply signal; the second voltage supply network is connected to the two portions of the at least one second voltage supply pad on two opposite sides of the display area.

In another aspect, the present disclosure provides a display apparatus, comprising the display substrate herein or fabricated by a method described herein, and one or more integrated circuits connected to the display substrate.

### BRIEF DESCRIPTION OF THE FIGURES

The following drawings are merely examples for illustrative purposes according to various disclosed embodiments and are not intended to limit the scope of the present invention.

FIG. 1 is a schematic diagram illustrating the structure of a display substrate in some embodiments according to the present disclosure.

FIG. 2 is a schematic diagram illustrating the structure of a display substrate in some embodiments according to the present disclosure.

FIG. 3 is a schematic diagram illustrating a display area and a peripheral area in a display substrate in some embodiments according to the present disclosure.

FIG. 4 is a schematic diagram illustrating the structure of at least one first voltage supply pad in some embodiments according to the present disclosure.

FIG. 5A is a schematic diagram illustrating the structure of a first portion of at least one second voltage supply pad in a first layer in some embodiments according to the present disclosure.

FIG. 5B is a schematic diagram illustrating the structure of a second portion of at least one second voltage supply pad in the second layer in some embodiments according to the present disclosure.

FIG. 6 is a schematic diagram illustrating the structure of a display substrate in some embodiments according to the present disclosure.

FIG. 7 is a schematic diagram illustrating the structure of a display substrate in some embodiments according to the present disclosure.

FIG. 8 shows a corner region of the display substrate depicted in FIG. 7.

FIG. 9A is a schematic diagram illustrating the structure of a portion of a display substrate in some embodiments according to the present disclosure.

FIG. 9B is a schematic diagram illustrating the structure of a conductive layer in a portion of a display substrate in some embodiments according to the present disclosure.

FIG. 9C is a schematic diagram illustrating the structure of a signal line layer in a portion of a display substrate in some embodiments according to the present disclosure.

FIG. 9D is a schematic diagram illustrating the structure of an anode material layer in a portion of a display substrate in some embodiments according to the present disclosure.

FIG. 9E is a schematic diagram illustrating the structure of a pixel definition layer and a light emitting layer in a portion of a display substrate in some embodiments according to the present disclosure.

FIG. 9F is a schematic diagram illustrating the structure of a cathode material layer in a portion of a display substrate in some embodiments according to the present disclosure.

FIG. 10A is a schematic diagram illustrating the structure of a portion of a display substrate in some embodiments according to the present disclosure.

FIG. 10B is a schematic diagram illustrating the structure of a conductive layer in a portion of a display substrate in some embodiments according to the present disclosure.

FIG. 10C is a schematic diagram illustrating the structure of a signal line layer in a portion of a display substrate in some embodiments according to the present disclosure.

FIG. 10D is a schematic diagram illustrating the structure of an anode material layer in a portion of a display substrate in some embodiments according to the present disclosure.

FIG. 10E is a schematic diagram illustrating the structure of a pixel definition layer and a light emitting layer in a portion of a display substrate in some embodiments according to the present disclosure.

FIG. 10F is a schematic diagram illustrating the structure of a cathode material layer in a portion of a display substrate in some embodiments according to the present disclosure.

FIG. 11 illustrates a cross-sectional view along an A-A′ line in FIG. 9A.

FIG. 12 illustrates a cross-sectional view along a B-B′ line in FIG. 10A.

FIG. 13 illustrates a first voltage supply network in a display area in some embodiments according to the present disclosure.

FIG. 14 illustrates a second voltage supply network in a display area in some embodiments according to the present disclosure.

FIG. 15 illustrates a first voltage supply network in a display area in some embodiments according to the present disclosure.

FIG. 16 illustrates a second voltage supply network in a display area in some embodiments according to the present disclosure.

FIG. 17 is a schematic diagram illustrating a region of a display substrate between a display area and a peripheral area of the display substrate in some embodiments according to the present disclosure.

FIG. 18A illustrates the structure of a border row and a border column in a display substrate in some embodiments according to the present disclosure.

FIG. 18B illustrate the structure of a portion of a first voltage supply network in a border row and a border column in a display substrate in some embodiments according to the present disclosure.

FIG. 18C illustrate the structure of a portion of a second voltage supply network in a border row and a border column in a display substrate in some embodiments according to the present disclosure.

FIG. 19A illustrates the structure of a border row and a border column in a display substrate in some embodiments according to the present disclosure.

FIG. 19B illustrate the structure of a portion of a first voltage supply network in a border row and a border column in a display substrate in some embodiments according to the present disclosure.

FIG. 19C illustrate the structure of a portion of a second voltage supply network in a border row and a border column in a display substrate in some embodiments according to the present disclosure.

FIG. 20 is a circuit diagram illustrating the structure of a pixel driving circuit for driving an active matrix light emitting diode in some embodiments according to the present disclosure.

### DETAILED DESCRIPTION

The disclosure will now be described more specifically with reference to the following embodiments. It is to be noted that the following descriptions of some embodiments are presented herein for purpose of illustration and description only. It is not intended to be exhaustive or to be limited to the precise form disclosed.

The present disclosure provides, inter alia, a display substrate and a display apparatus that substantially obviate one or more of the problems due to limitations and disadvantages of the related art. In one aspect, the present disclosure provides a display substrate. In some embodiments, the display substrate includes a plurality of islands and a plurality of bridges connecting the plurality of islands. Optionally, the display substrate includes a first voltage supply network. Optionally, the first voltage supply network includes a plurality of first connecting structures in a display area of the display substrate, a first row connecting line, a second row connecting line, a first column connecting line, and a second column connecting line. Optionally, a respective first connecting structure of the plurality of first connecting structures is connected by the first row connecting line, the second row connecting line, the first column connecting line, and the second column connecting line, to four adjacent first connecting structures, respectively. Optionally, the first row connecting line, the second row connecting line, the first column connecting line, and the second column connecting line are in four different bridges of the plurality of bridges.

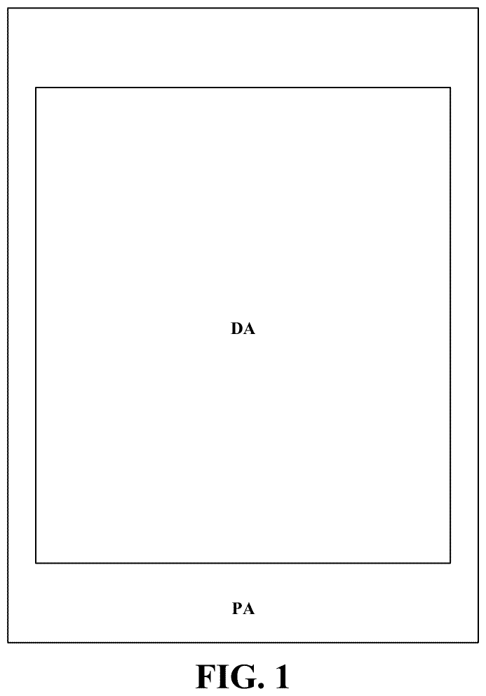

FIG. 1 is a schematic diagram illustrating the structure of a display substrate in some embodiments according to the present disclosure. Referring to FIG. 1, the display substrate in some embodiments includes a display area DA and a peripheral area PA. As used herein, the term “display area” refers to an area of a display substrate (e.g., an opposing substrate or an array substrate) in a display panel where image is actually displayed. Optionally, the display area may include both a subpixel region and an inter-subpixel region. A subpixel region refers to a light emission region of a subpixel, such as a region corresponding to a pixel electrode in a liquid crystal display or a region corresponding to a light emissive layer in an organic light emitting diode display panel. An inter-subpixel region refers to a region between adjacent subpixel regions, such as a region corresponding to a black matrix in a liquid crystal display or a region corresponding a pixel definition layer in an organic light emitting diode display panel. Optionally, the inter-subpixel region is a region between adjacent subpixel regions in a same pixel. Optionally, the inter-subpixel region is a region between two adjacent subpixel regions from two adjacent pixels. As used herein the term “peripheral area” refers to an area of a display substrate (e.g., an opposing substrate or an array substrate) in a display panel where various circuits and wires are provided to transmit signals to the display substrate. To increase the transparency of the display apparatus, non-transparent or opaque components of the display apparatus (e.g., battery, printed circuit board, metal frame), can be disposed in the peripheral area rather than in the display areas.

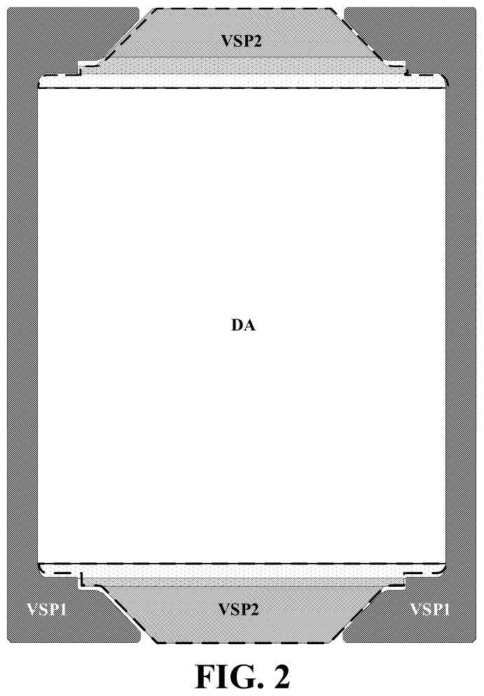

FIG. 2 is a schematic diagram illustrating the structure of a display substrate in some embodiments according to the present disclosure. Referring to FIG. 2, the display substrate in some embodiments includes at least one first voltage supply pad VSP1 and at least one second voltage supply pad VSP2 in the peripheral area. The at least one first voltage supply pad VSP1 is configured to provide a first voltage signal to subpixels in the display area DA. The at least one second voltage supply pad VSP2 is configured to provide a second voltage signal to subpixels in the display area DA.

Various implementations may be practiced in the present disclosure. The at least one first voltage supply pad VSP1 and the at least one second voltage supply pad VSP2 may be configured to provide various appropriate voltage signals to the subpixels in the display area DA. In one example, the at least one first voltage supply pad VSP1 is configured to provide a voltage (e.g., a Vss voltage) to cathodes of the subpixels in the display area DA; and the at least one second voltage supply pad VSP2 is configured to provide a high voltage (e.g., a Vdd voltage) to the subpixels in the display area DA. In another example, the at least one first voltage supply pad VSP1 is configured to provide a high voltage (e.g., a Vdd voltage) to the subpixels in the display area DA; and the at least one second voltage supply pad VSP2 is configured to provide a voltage (e.g., a Vss voltage) to cathodes of the subpixels in the display area DA.

Referring to FIG. 2, the at least one first voltage supply pad VSP1 in some embodiments substantially surrounds the display area DA. As used herein the term “substantially surrounding” refers to surrounding at least 50% (e.g., at least 60%, at least 70%, at least 80%, at least 90%, at least 95%, at least 99%, and 100%) of a perimeter of an area.

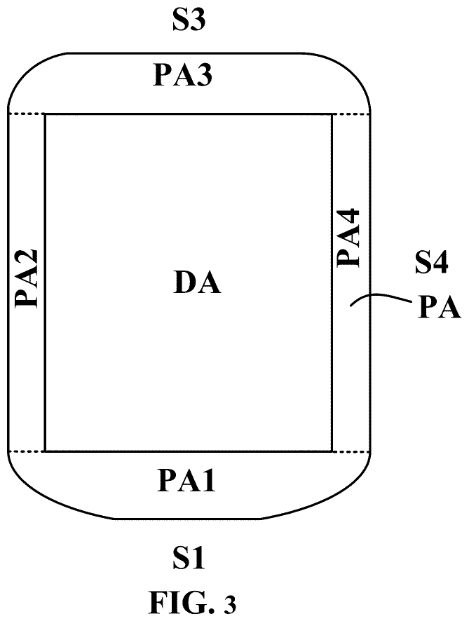

FIG. 3 is a schematic diagram illustrating a display area and a peripheral area in a display substrate in some embodiments according to the present disclosure. Referring to FIG. 3, in some embodiments, the display substrate includes a display area DA and a peripheral area PA. In some embodiments, the peripheral area PA includes a first sub-area PA1 on a first side S1 of the display area DA, a second sub-area PA2 on a second side S2 of the display area DA, a third sub-area PA3 on a third side S3 of the display area DA, a fourth sub-area PA4 on a fourth side S4 of the display area DA. Optionally, the first side S1 and the third side S3 are opposite to each other. Optionally, the second side S2 and the fourth side S4 are opposite to each other. Optionally, the first sub-area PA1 is a sub-area where signal lines of the display substrate are connected to an integrated circuit.

Referring to FIG. 2 and FIG. 3, the at least one first voltage supply pad VSP1 in some embodiments is at least partially in the first sub-area PA1, at least partially in the second sub-area PA2, at least partially in the third sub-area PA3, and at least partially in the fourth sub-area PA4. The at least one first voltage supply pad VSP1 is configured to provide the first voltage supply signal to the display area DA from two opposite sides (e.g., the first side S1 and the third side S3, or the second side S2 and the fourth side S4). The structure according to the present disclosure can reduce brightness non-uniformity due to IR drop in the signal lines across the display area DA.

Referring to FIG. 2 and FIG. 3, the at least one second voltage supply pad VSP2 in some embodiments is at least partially in the first sub-area PA1, and at least partially in the third sub-area PA3. The at least one second voltage supply pad VSP2 is configured to provide the second voltage supply signal to the display area DA from two opposite sides (e.g., the first side S1 and the third side S3). The structure according to the present disclosure can reduce brightness non-uniformity due to IR drop in the signal lines across the display area DA.

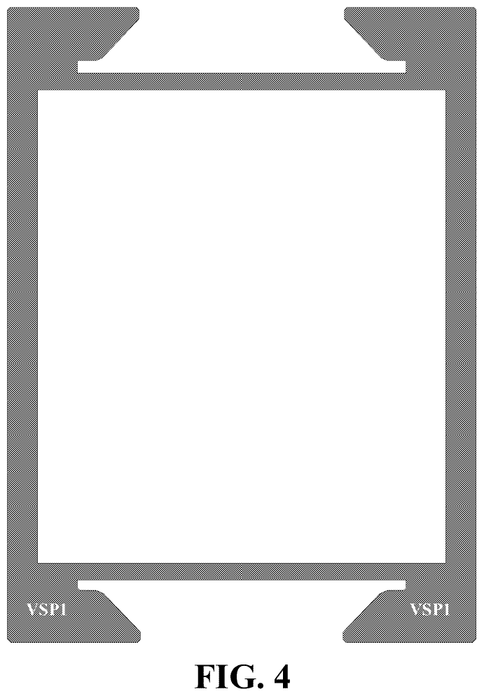

FIG. 4 is a schematic diagram illustrating the structure of at least one first voltage supply pad in some embodiments according to the present disclosure. Referring to FIG. 4, in some embodiments, the at least one first voltage supply pad VSP1 is in a first layer (e.g., a signal line layer) of the display substrate. The display substrate further includes a plurality of first voltage supply lines in the display area DA. Optionally, the at least one first voltage supply pad VSP1 and at least portions of the plurality of first voltage supply lines are in the first layer.

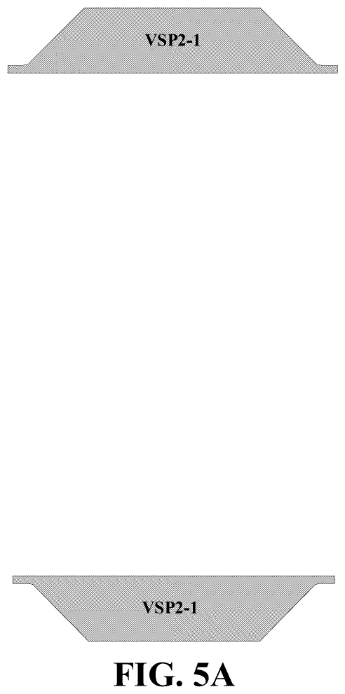

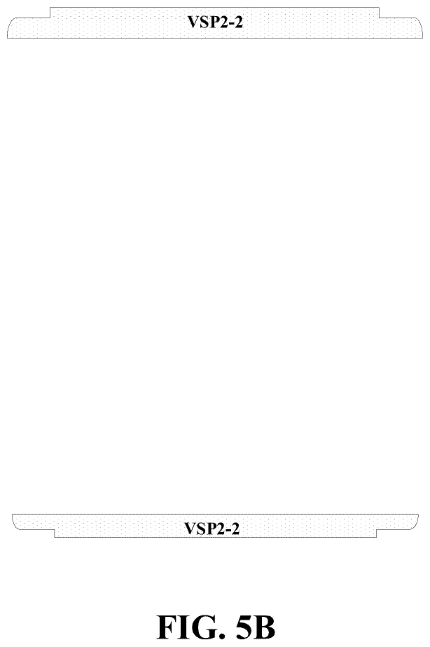

FIG. 5A is a schematic diagram illustrating the structure of a first portion of at least one second voltage supply pad in a first layer in some embodiments according to the present disclosure. Referring to FIG. 5A, the at least one second voltage supply pad in some embodiments includes a first portion VSP2-1 in the first layer (e.g., a signal line layer) of the display substrate. The display substrate further includes a plurality of second voltage supply lines in the display area DA. Optionally, the first portion VSP2-1 and at least portions of the plurality of second voltage supply lines are in the first layer.

FIG. 5B is a schematic diagram illustrating the structure of a second portion of at least one second voltage supply pad in the second layer in some embodiments according to the present disclosure. Referring to FIG. 5B, the at least one second voltage supply pad in some embodiments includes a second portion VSP2-2 in the second layer (e.g., an anode material layer) of the display substrate.

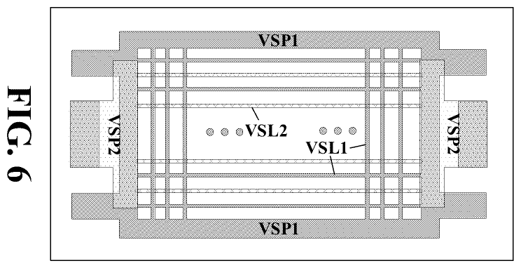

FIG. 6 is a schematic diagram illustrating the structure of a display substrate in some embodiments according to the present disclosure. Referring to FIG. 6, the display substrate in some embodiments further includes a plurality of first voltage supply lines VSL1 and a plurality of second voltage supply lines VSL2. The plurality of first voltage supply lines VSL1 optionally includes first voltage supply lines extending along a first direction (e.g., between the first sub-area PA1 and the third sub-area PA2 depicted in FIG. 3), and first voltage supply lines extending along a second direction (e.g., between the second sub-area PA2 and the fourth sub-area PA4 depicted in FIG. 3). Optionally, a respective first voltage supply line of the plurality of first voltage supply lines VSL1 is electrically connected to portions of the at least one first voltage supply pad VSP1 on two opposite sides (e.g., the first side S1 and the third side S3 depicted in FIG. 3, or the second side S2 and the fourth side S4 depicted in FIG. 3) of the display area, respectively. Optionally, a respective second voltage supply line of the plurality of second voltage supply lines VSL2 is electrically connected to portions of the at least one second voltage supply pad VSP2 on two opposite sides (e.g., the first side S1 and the third side S3 depicted in FIG. 3) of the display area, respectively.

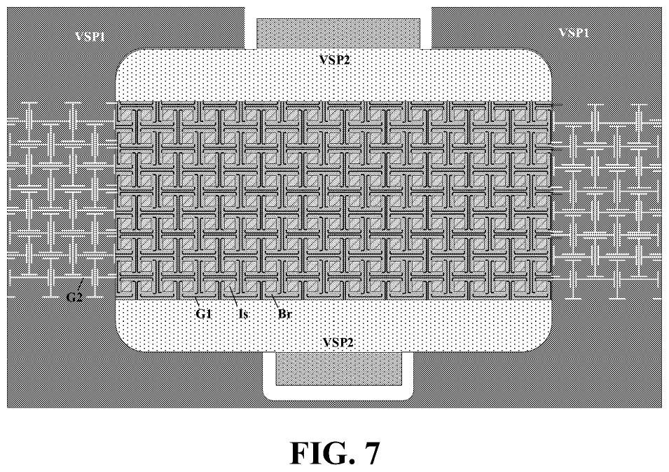

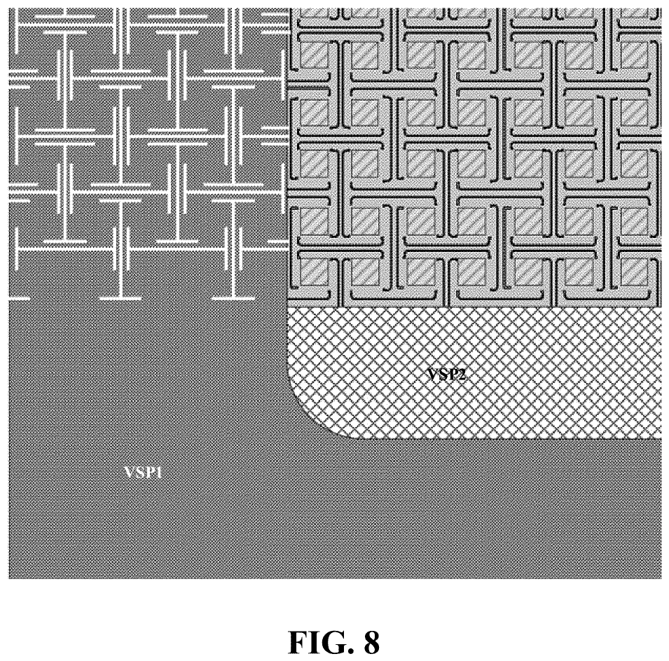

FIG. 7 is a schematic diagram illustrating the structure of a display substrate in some embodiments according to the present disclosure. FIG. 8 shows a corner region of the display substrate depicted in FIG. 7. Referring to FIG. 7 and FIG. 8, the display substrate in some embodiments is a stretchable display substrate. As used herein, the term “stretchable” refers to the ability of a material, structure, device or device component to be strained in tension (e.g., being made longer and/or wider) without undergoing permanent deformation or failure such as fracture, e.g., the ability to elongate at least 10% of its length without permanently deforming, tearing, or breaking. The term is also meant to encompass substrates having components (whether or not the components themselves are individually stretchable as stated above) that are configured in such a way so as to accommodate a stretchable, inflatable, or expandable surface and remain functional when applied to a stretchable, inflatable, or otherwise expandable surface that is stretched, inflated, or otherwise expanded respectively. The term is also meant to encompass substrates that may be elastically and/or plastically deformable (i.e. after being stretched, the substrate may return to its original size when the stretching force is released or the substrate may not return to its original size and in some examples, may remain in the stretched form) and the deformation (i.e. stretching and optionally flexing) may occur during manufacture of the substrate (e.g. with the substrate being stretched and optionally flexed to form its final shape), during assembly of a device incorporating the substrate (which may be considered part of the manufacturing operation) and/or during use (e.g. with the user being able to stretch and optionally flex the substrate).

In some embodiments, in the display area, the display substrate includes a plurality of islands Is and a plurality of bridges Br connecting the plurality of islands Is (discussed further in details below). A respective island of the plurality of islands Is includes at least one display element (e.g., at least one light emitting diode). The display substrate further includes a plurality of first gaps G1 at least partially extending into (e.g., extending through) the display substrate. A respective first gap of the plurality of first gaps G1 is between adjacent islands of the plurality of islands.

In some embodiments, in the peripheral area, the display substrate includes a plurality of second gaps G2 at least partially extending into (e.g., extending through) the display substrate. The presence of the plurality of second gaps G2 renders at least a portion of the peripheral area of the display substrate stretchable, at least in a region having the plurality of second gaps G2.

Referring to FIG. 3 and FIG. 7, in some embodiments, the plurality of second gaps G2 are present in the second sub-area PA2 and the fourth sub-area PA4, and are absent in the first sub-area PA1 and the third sub-area PA3. The display substrate is stretchable in the second sub-area PA2 and the fourth sub-area PA4, and is less stretchable (e.g., non-stretchable) in the first sub-area PA1 and the third sub-area PA3. Alternatively, in another example, the display substrate may be at least partially stretchable in all four sub-areas, including the first sub-area PA1, the second sub-area PA2, the third sub-area PA3, and the fourth sub-area PA4.

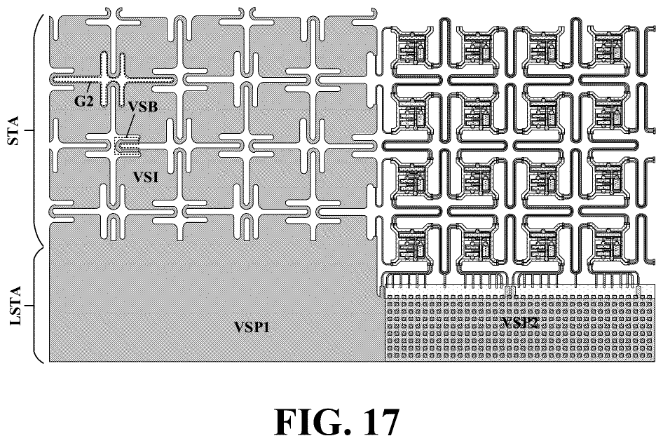

FIG. 17 is a schematic diagram illustrating a region of a display substrate between a display area and a peripheral area of the display substrate in some embodiments according to the present disclosure. Referring to FIG. 3, FIG. 7, and FIG. 17, the display substrate is stretchable in a stretchable area STA, and is less stretchable (e.g., non-stretchable) in a less stretchable area LSTA. The at least one first voltage supply pad VSP1 extends from the less stretchable area LSTA into the stretchable area STA.

In the stretchable area STA, the at least one first voltage supply pad VSP1 includes a plurality of voltage supply islands VSI and a plurality of voltage supply bridges VSB connecting the plurality of voltage supply islands VSI. The display substrate further includes a plurality of second gaps G2 at least partially extending into (e.g., extending through) the display substrate. A respective second gap of the plurality of second gaps G2 is between adjacent voltage supply islands of the plurality of voltage supply islands VSI. The plurality of voltage supply islands VSI, the plurality of voltage supply bridges VSB, and the plurality of second gaps G2 may have a pattern similar to a pattern of the plurality of islands Is, the plurality of bridges Br, and the plurality of first gaps G1 in the display area of the display substrate. Alternatively, the plurality of voltage supply islands VSI, the plurality of voltage supply bridges VSB, and the plurality of second gaps G2 may have a pattern different from a pattern of the plurality of islands Is, the plurality of bridges Br, and the plurality of first gaps G1 in the display area of the display substrate. In the example depicted in FIG. 17, a respective voltage supply island of the plurality of voltage supply islands VS1 is connected to four adjacent voltage supply islands of the plurality of voltage supply islands VS1 through four voltage supply bridges of the plurality of voltage supply bridges VSB, respectively. The four adjacent voltage supply islands connected to the respective voltage supply island include two voltage supply islands in a same row as the respective voltage supply island and two voltage supply islands in a same column as the respective voltage supply island.

In the less stretchable area LSTA, the at least one first voltage supply pad VSP1 has a different layout. In some embodiments, a portion of the at least one first voltage supply pad VSP1 in the less stretchable area LSTA does not have the plurality of voltage supply islands VSI, the plurality of voltage supply bridges VSB, or the plurality of second gaps G2. In one example depicted in FIG. 17, the portion of the at least one first voltage supply pad VSP1 in the less stretchable area LSTA is a layer continuously extending throughout a substantially entire area of the less stretchable area LSTA. In another example, in the less stretchable area LSTA, the display substrate may include one or more vias extending through the portion of the at least one first voltage supply pad VSP1.

Referring to FIG. 3, FIG. 7, and FIG. 17, the at least one second voltage supply pad VSP2 may be disposed in the less stretchable area LSTA. In alternative embodiments, at least a portion of the at least one second voltage supply pad VSP2 may be disposed in the stretchable area STA.

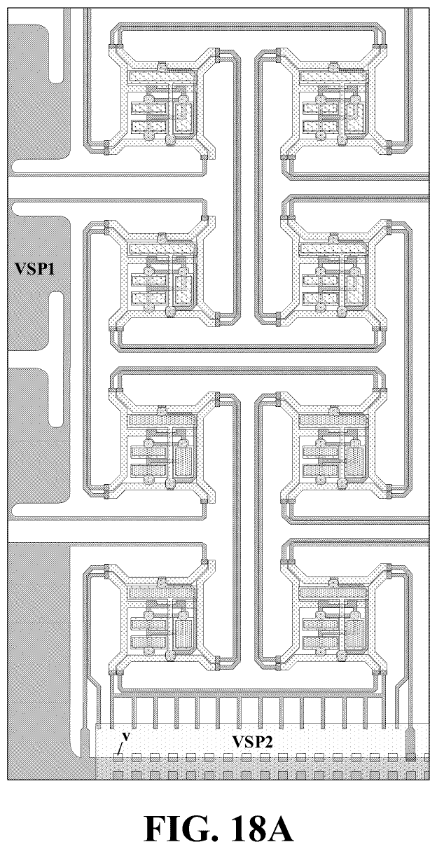

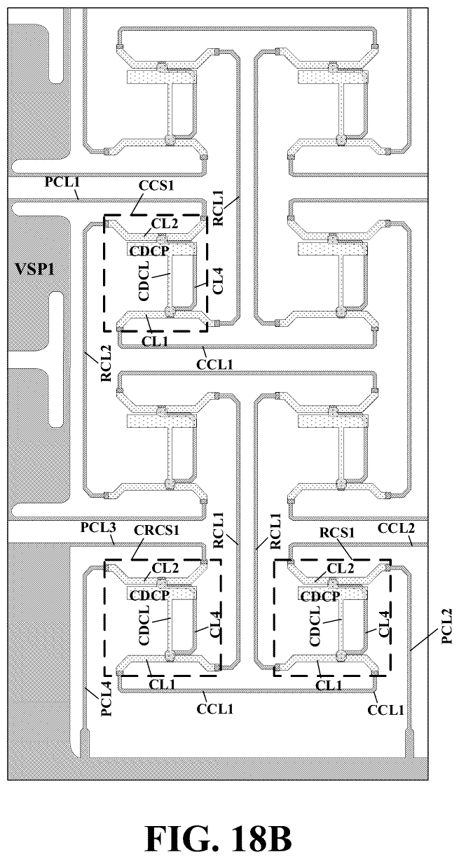

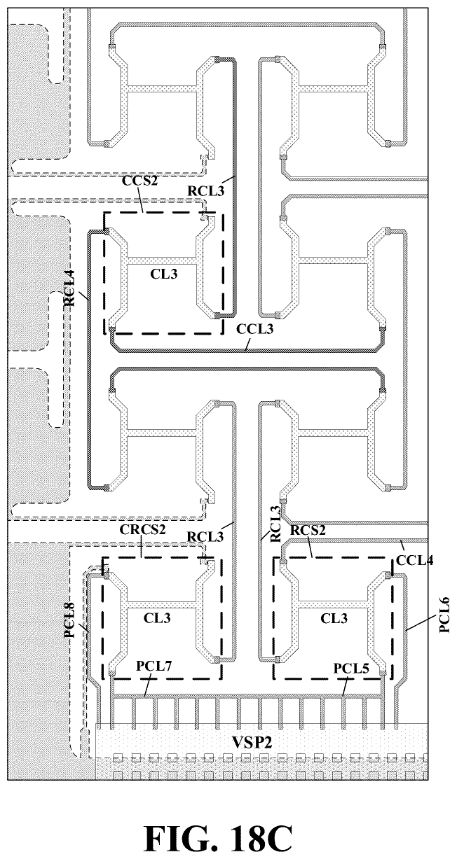

FIG. 18A illustrates the structure of a border row and a border column in a display substrate in some embodiments according to the present disclosure. Referring to FIG. 3, FIG. 7, FIG. 17, and FIG. 18A, the at least one second voltage supply pad VSP2 in some embodiments is a layer lacking islands and bridges. In one example, the display substrate includes a plurality of vias v (e.g., gas releasing vias) extending through the at least one second voltage supply pad VSP2.

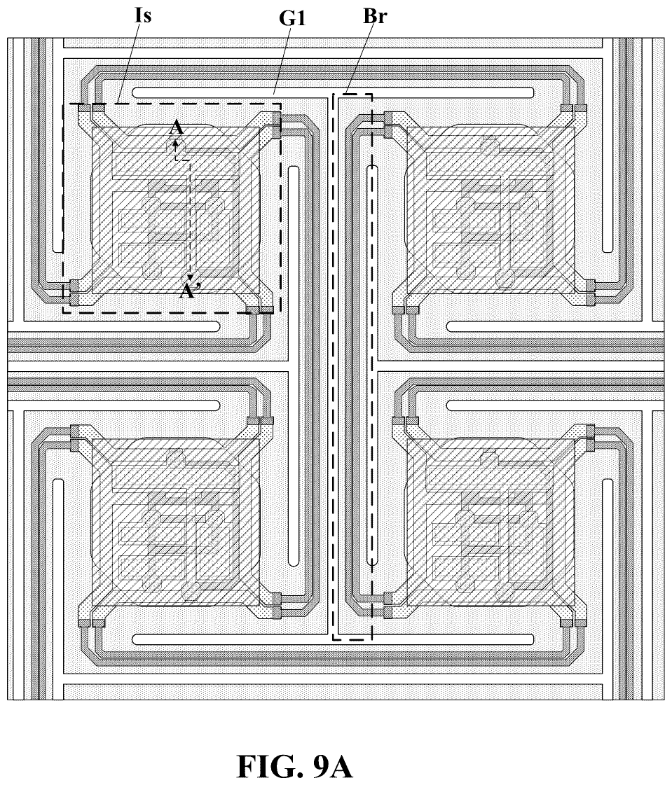

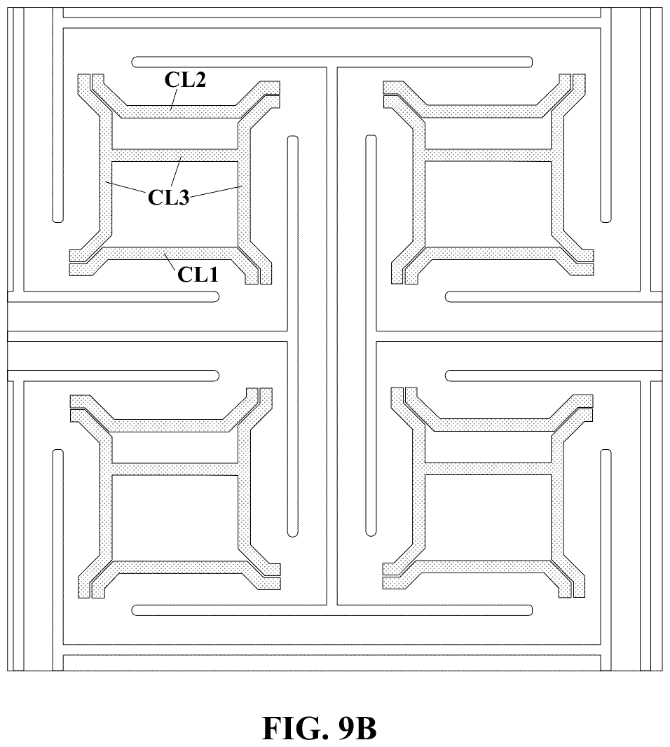

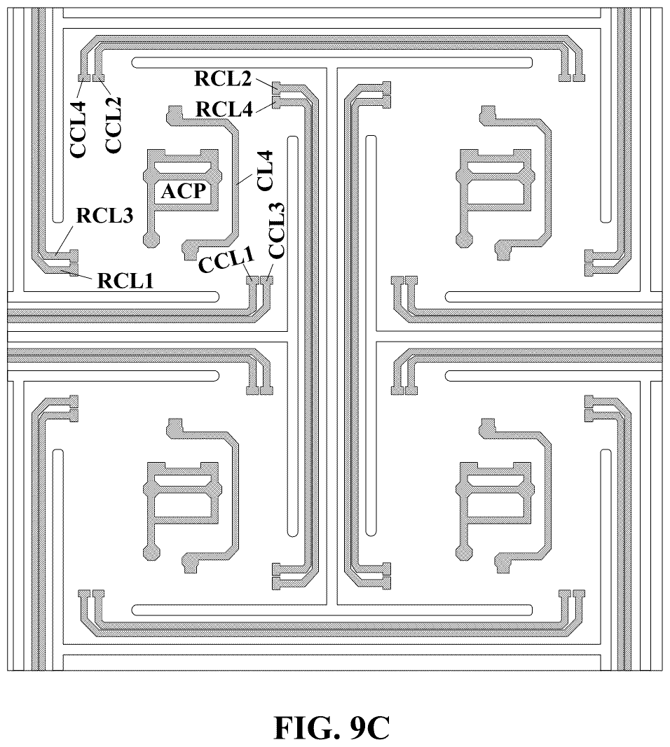

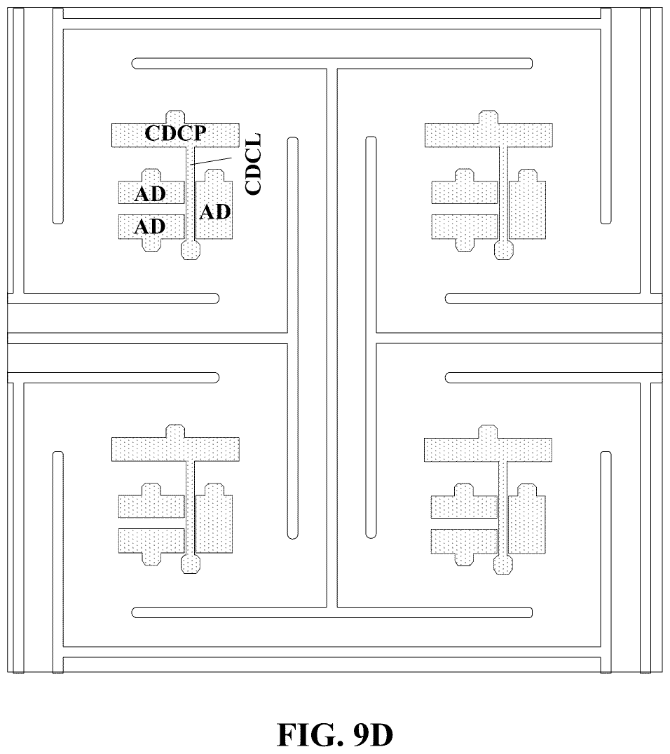

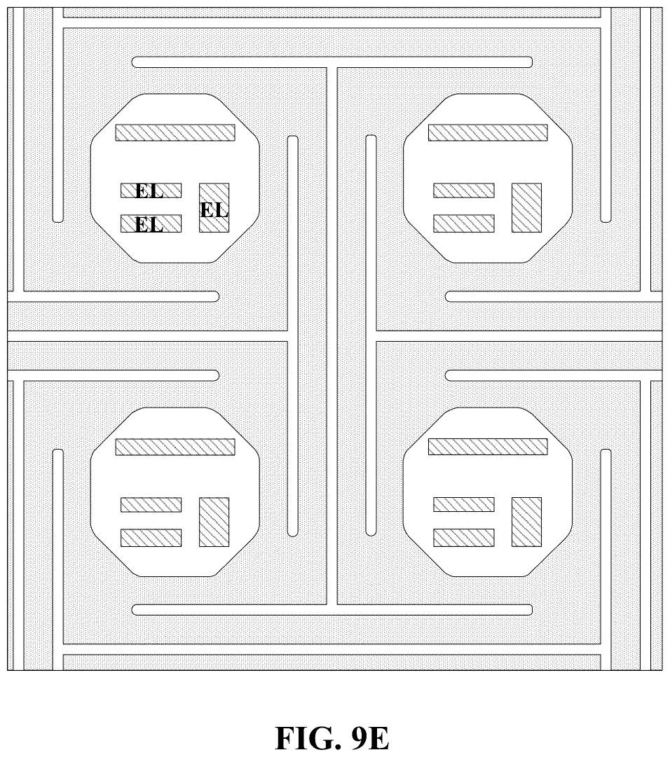

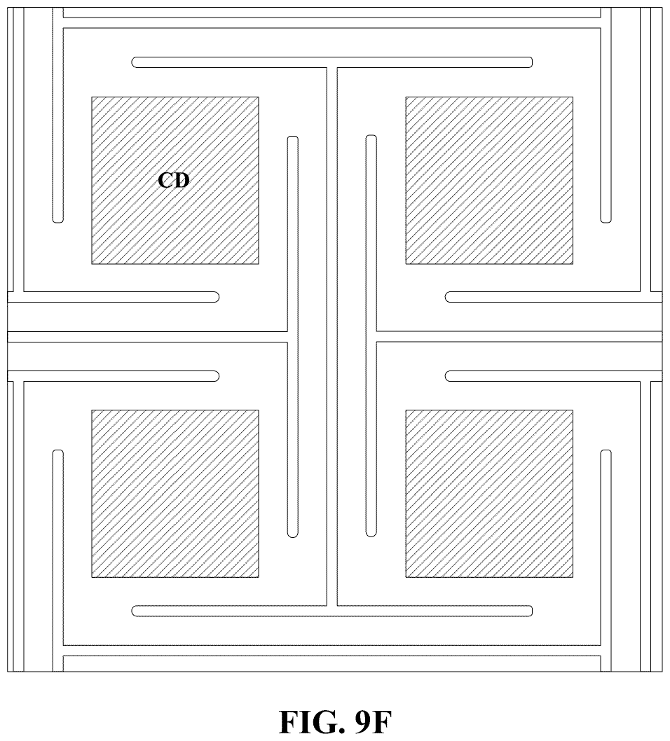

FIG. 9A is a schematic diagram illustrating the structure of a portion of a display substrate in some embodiments according to the present disclosure. FIG. 9B is a schematic diagram illustrating the structure of a conductive layer in a portion of a display substrate in some embodiments according to the present disclosure. FIG. 9C is a schematic diagram illustrating the structure of a signal line layer in a portion of a display substrate in some embodiments according to the present disclosure. FIG. 9D is a schematic diagram illustrating the structure of an anode material layer in a portion of a display substrate in some embodiments according to the present disclosure. FIG. 9E is a schematic diagram illustrating the structure of a pixel definition layer and a light emitting layer in a portion of a display substrate in some embodiments according to the present disclosure. FIG. 9F is a schematic diagram illustrating the structure of a cathode material layer in a portion of a display substrate in some embodiments according to the present disclosure. Referring to FIG. 9A to FIG. 9F, a respective first gap of the plurality of first gaps G1 in some embodiments has a I shape. At least one of the plurality of islands Is is connected to four bridges of the plurality of bridges Br. A respective bridge of the plurality of bridges Br connects two adjacent islands of the plurality of islands Is. The respective bridge extends in a direction substantially parallel to a column direction or a row direction of an array of the plurality of islands Is.

Referring to FIG. 9A and FIG. 9B, the display substrate in the conductive layer includes a first connecting line CL1, a second connecting line CL2, and a third connecting line CL3. Optionally, the first connecting line CL1, the second connecting line CL2, and the third connecting line CL3 are in a respective island of the plurality of islands Is. In one example depicted in FIG. 9B, the third connecting line CL3 spaces apart the first connecting line CL1 and the second connecting line CL2. The third connecting line CL3 may have various appropriate shapes. In one particular example, the third connecting line CL3 has pseudo H shape. As discussed further in details below, the first connecting line CL1 and the second connecting line CL2 are parts of a first voltage supply network (e.g., parts of a respective first voltage supply line of the plurality of first voltage supply lines VSL1). The third connecting line CL3 is a part of a second voltage supply network (e.g., a part of a respective second voltage supply line of the plurality of second voltage supply lines VSL2). The first connecting line CL1 and the second connecting line CL2 are configured to be provided with a first voltage supply signal. The third connecting line CL3 is configured to be provided with a second voltage supply signal.

Referring to FIG. 9A and FIG. 9C, the display substrate in the signal line layer includes a plurality of row connecting lines and a plurality of column connecting lines. An individual one of the plurality of row connecting lines and the plurality of column connecting lines is at least partially in an individual bridge of the plurality of bridges Br.

In some embodiments, the display substrate in the signal line layer includes a first row connecting line RCL1 at least partially in an individual bridge of the plurality of bridges Br, the first row connecting line RCL1 electrically connects the first connecting line CL1 in a respective island of the plurality of islands Is with an adjacent island of the plurality of islands Is in a first adjacent row (e.g., a previous row or a next row) and in a same column, for example, with a second connecting line CL2 in the adjacent island of the plurality of islands Is in the first adjacent row (e.g., the previous row or the next row) and in the same column.

In some embodiments, the display substrate in the signal line layer includes a second row connecting line RCL2 at least partially in an individual bridge of the plurality of bridges Br, the second row connecting line RCL2 electrically connects the second connecting line CL2 in a respective island of the plurality of islands Is with an adjacent island of the plurality of islands Is in a second adjacent row (e.g., a next row or a previous row) and in a same column, for example, with a first connecting line CL1 in the adjacent island of the plurality of islands Is in the second adjacent row (e.g., the next row or the previous row) and in the same column. The first adjacent row and the second adjacent row are two different rows on two different sides, along a column direction, of a present row having the respective island of the plurality of islands Is.

In some embodiments, the display substrate in the signal line layer includes a first column connecting line CCL1 at least partially in an individual bridge of the plurality of bridges Br, the first column connecting line CCL1 electrically connects the first connecting line CL1 in a respective island of the plurality of islands Is with an adjacent island of the plurality of islands Is in a first adjacent column (e.g., a previous column or a next column) and in a same row, for example, with a first connecting line CL1 in the adjacent island of the plurality of islands Is in the first adjacent column (e.g., the previous column or the next column) and in the same row.

In some embodiments, the display substrate in the signal line layer includes a second column connecting line CCL2 at least partially in an individual bridge of the plurality of bridges Br, the second column connecting line CCL2 electrically connects the second connecting line CL2 in a respective island of the plurality of islands Is with an adjacent island of the plurality of islands Is in a second adjacent column (e.g., a next column or a previous column) and in a same row, for example, with a second connecting line CL2 in the adjacent island of the plurality of islands Is in the second adjacent column (e.g., the next column or the previous column) and in the same row. The first adjacent column and the second adjacent column are two different columns on two different sides, along a row direction, of a present column having the respective island of the plurality of islands Is.

In some embodiments, the display substrate in the signal line layer includes a third row connecting line RCL3 at least partially in an individual bridge of the plurality of bridges Br, the third row connecting line RCL3 electrically connects the third connecting line CL3 in a respective island of the plurality of islands Is with an adjacent island of the plurality of islands Is in a first adjacent row (e.g., a previous row or a next row) and in a same column, for example, with a third connecting line CL3 in the adjacent island of the plurality of islands Is in the first adjacent row (e.g., the previous row or the next row) and in the same column.

In some embodiments, the display substrate in the signal line layer includes a fourth row connecting line RCL4 at least partially in an individual bridge of the plurality of bridges Br, the fourth row connecting line RCL4 electrically connects the third connecting line CL3 in a respective island of the plurality of islands Is with an adjacent island of the plurality of islands Is in a second adjacent row (e.g., a next row or a previous row) and in a same column, for example, with a third connecting line CL3 in the adjacent island of the plurality of islands Is in the second adjacent row (e.g., the next row or the previous row) and in the same column. The first adjacent row and the second adjacent row are two different rows on two different sides, along a column direction, of a present row having the respective island of the plurality of islands Is.

In some embodiments, the display substrate in the signal line layer includes a third column connecting line CCL3 at least partially in an individual bridge of the plurality of bridges Br, the third column connecting line CCL3 electrically connects the third connecting line CL3 in a respective island of the plurality of islands Is with an adjacent island of the plurality of islands Is in a first adjacent column (e.g., a previous column or a next column) and in a same row, for example, with a third connecting line CL3 in the adjacent island of the plurality of islands Is in the first adjacent column (e.g., the previous column or the next column) and in the same row.

In some embodiments, the display substrate in the signal line layer includes a fourth column connecting line CCL4 at least partially in an individual bridge of the plurality of bridges Br, the fourth column connecting line CCL4 electrically connects the third connecting line CL3 in a respective island of the plurality of islands Is with an adjacent island of the plurality of islands Is in a second adjacent column (e.g., a next column or a previous column) and in a same row, for example, with a third connecting line CL3 in the adjacent island of the plurality of islands Is in the second adjacent column (e.g., the next column or the previous column) and in the same row. The first adjacent column and the second adjacent column are two different columns on two different sides, along a row direction, of a present column having the respective island of the plurality of islands Is.

Referring to FIG. 9A and FIG. 9C, the display substrate in the signal line layer includes a fourth connecting line CL4 in a respective island of the plurality of islands Is. The fourth connecting line CL4 electrically connects the first connecting line CL1 and the second connecting line CL2 in a same island of the plurality of islands Is.

Referring to FIG. 9A and FIG. 9C, the display substrate in the signal line layer includes an anode connecting pad ACP in a respective island of the plurality of islands Is. The anode connecting pad ACP electrically connects one or more anode with the third connecting line CL3, thereby providing the first voltage supply signal to the one or more anode.

Referring to FIG. 9A to FIG. 9D, the display substrate in the anode material layer in some embodiments includes one or more anode AD, a cathode connecting pad CDCP, and a cathode connecting line CDCL. The one or more anode AD, the cathode connecting pad CDCP, and the cathode connecting line CDCL are at least partially in a respective island of the plurality of islands Is. Optionally, the cathode connecting pad CDCP and the cathode connecting line CDCL are parts of a unitary structure. The cathode connecting pad CDCP and the cathode connecting line CDCL electrically connect the first connecting line CL1 to a cathode in the respective island, and electrically connect the second connecting line CL2 to the cathode in the respective island, thereby providing a second voltage supply signal to the cathode.

Referring to FIG. 9A to FIG. 9E, the display substrate includes the pixel definition layer PDL that defines a subpixel aperture. In some embodiments, the display substrate in the light emitting layer includes one or more light emitting blocks EL. An orthographic projection of the one or more light emitting blocks EL on a base substrate at least partially overlaps with an orthographic projection of the one or more anodes on a base substrate.

Referring to FIG. 9A to FIG. 9F, the display substrate in the cathode material layer includes a cathode CD in a respective island of the plurality of islands Is.

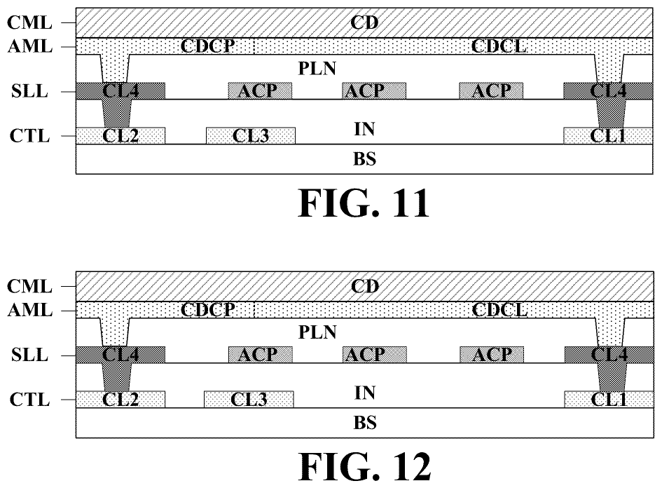

FIG. 11 illustrates a cross-sectional view along an A-A′ line in FIG. 9A. Referring to FIG. 11, and FIG. 9A to FIG. 9F, in some embodiments, the display substrate includes a base substrate BS, a conductive layer CTL on the base substrate BS, an insulating layer IN on a side of the conductive layer CTL away from the base substrate BS, a signal line layer SLL on a side of the insulating layer IN away from the base substrate BS, a planarization layer PLN on a side of the signal line layer SLL away from the base substrate BS, an anode material layer on a side of the planarization layer PLN away from the base substrate BS, and a cathode material layer CML on a side of the anode material layer AML away from the base substrate BS.

In some embodiments, the cathode connecting pad CDCP and the cathode connecting line CDCL is connected to (e.g., in direct contact with) the cathode CD. The cathode connecting pad CDCP is connected to the fourth connecting line CL4 through a via extending through the planarization layer PLN. The cathode connecting line CDCL is connected to the fourth connecting line CL4 through a via extending through the planarization layer PLN. The fourth connecting line CL4 is connected to the second connecting line CL2 through a via extending through the insulating layer IN. The fourth connecting line CL4 is connected to the first connecting line CL1 through a via extending through the insulating layer IN. The cathode CD is electrically connected to the first connecting line CL1 and is electrically connected to the second connecting line CL2, thereby receiving a second voltage supply signal from the first connecting line CL1 and the second connecting line CL2.

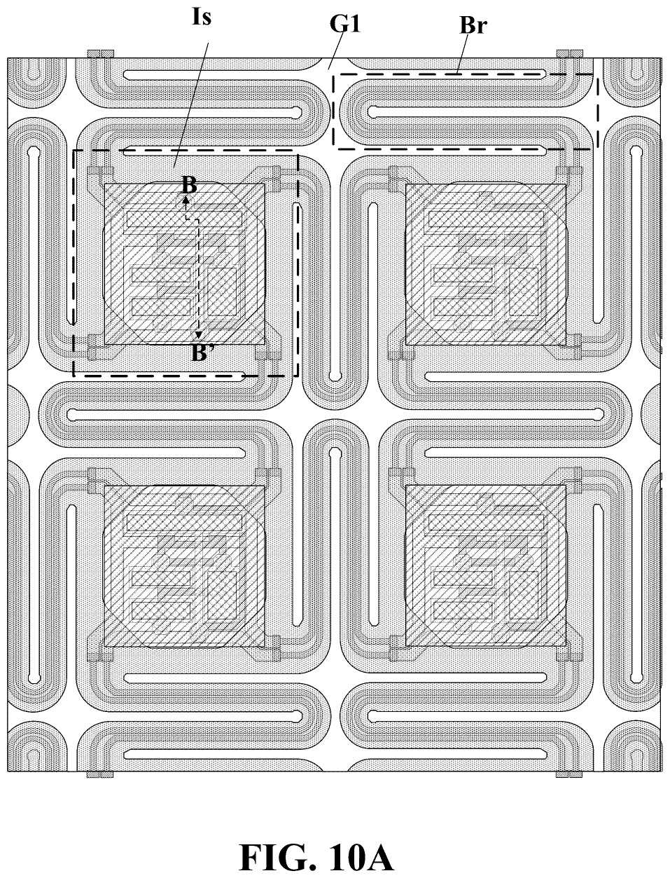

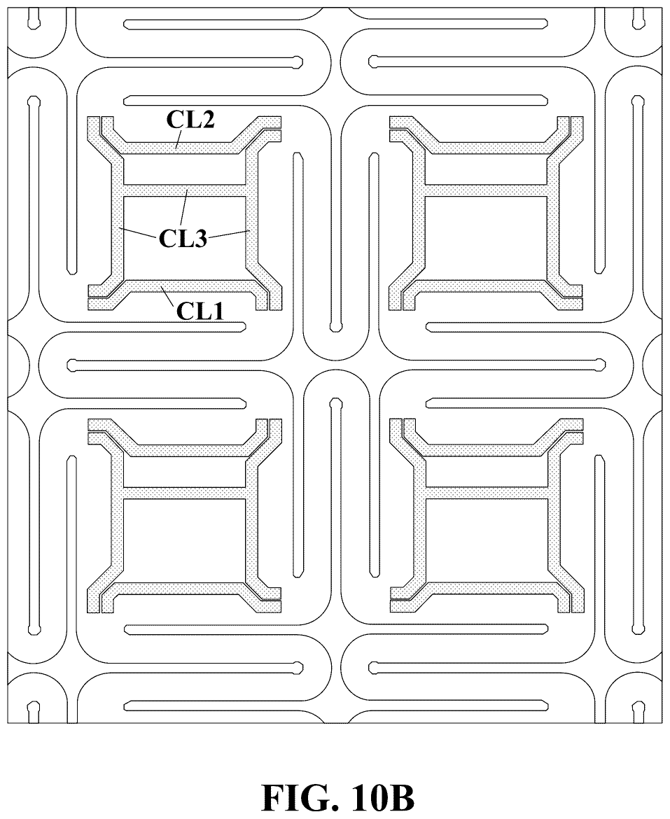

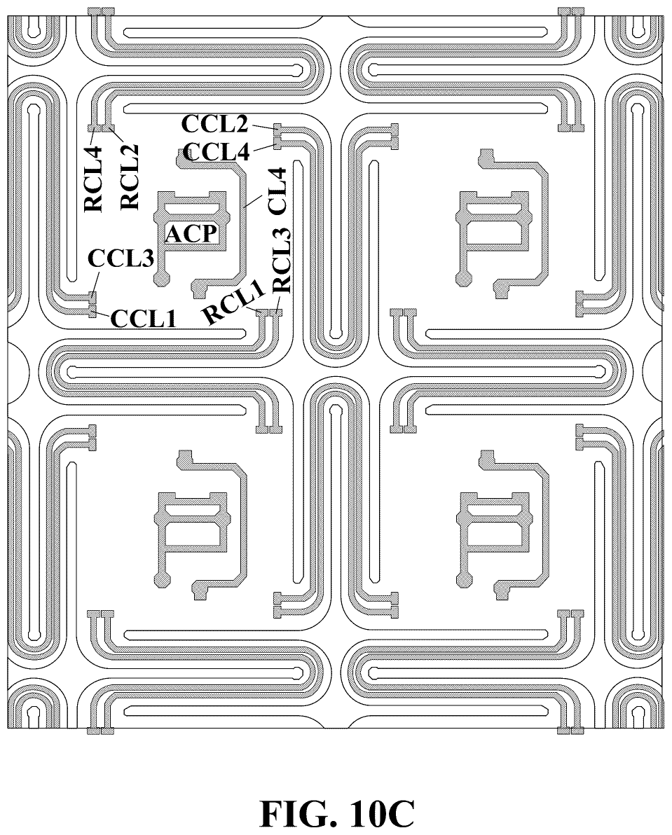

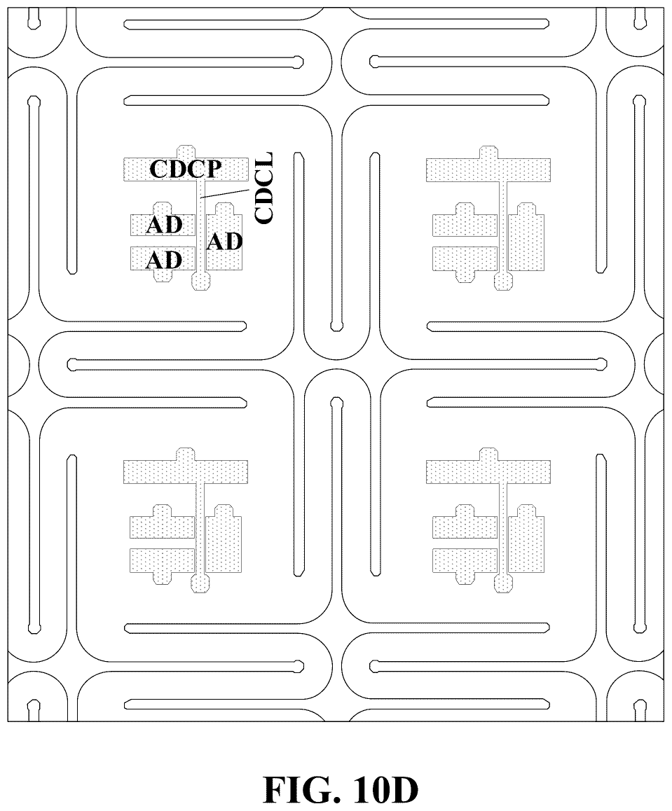

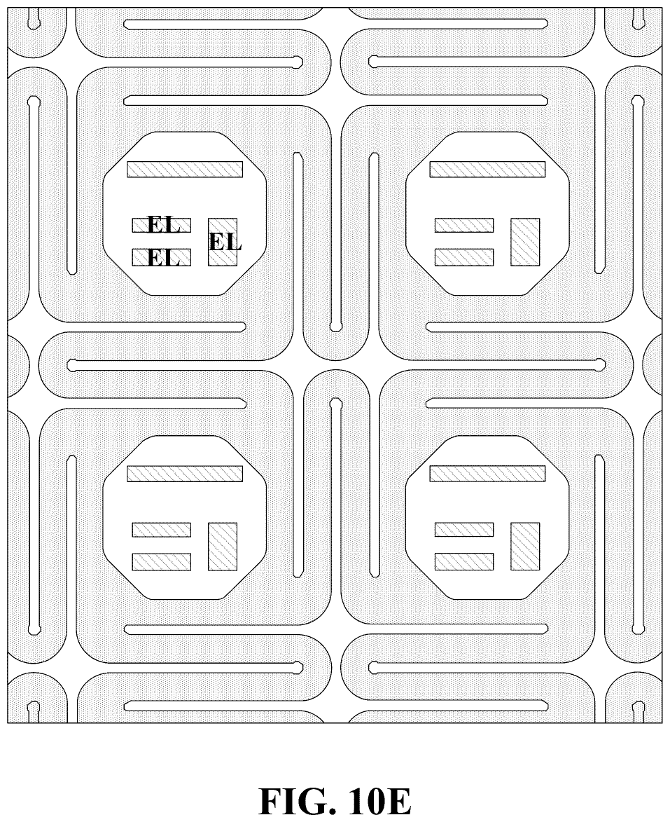

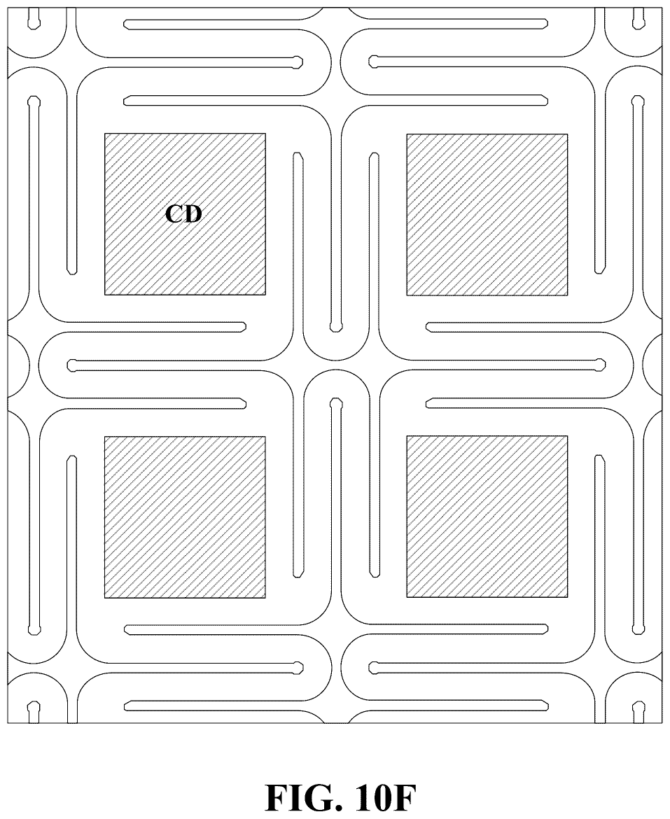

FIG. 10A is a schematic diagram illustrating the structure of a portion of a display substrate in some embodiments according to the present disclosure. FIG. 10B is a schematic diagram illustrating the structure of a conductive layer in a portion of a display substrate in some embodiments according to the present disclosure. FIG. 10C is a schematic diagram illustrating the structure of a signal line layer in a portion of a display substrate in some embodiments according to the present disclosure. FIG. 10D is a schematic diagram illustrating the structure of an anode material layer in a portion of a display substrate in some embodiments according to the present disclosure. FIG. 10E is a schematic diagram illustrating the structure of a pixel definition layer and a light emitting layer in a portion of a display substrate in some embodiments according to the present disclosure. FIG. 10F is a schematic diagram illustrating the structure of a cathode material layer in a portion of a display substrate in some embodiments according to the present disclosure. Referring to FIG. 10A to FIG. 10F, a respective first gap of the plurality of first gaps G1 in some embodiments has a ≠shape. At least one of the plurality of islands Is is connected to four bridges of the plurality of bridges Br. A respective bridge of the plurality of bridges Br connects two adjacent islands of the plurality of islands Is. The respective bridge has a hairpin shape. The respective bridge extends in a direction substantially parallel to a column direction or a row direction of an array of the plurality of islands Is.

Referring to FIG. 10A and FIG. 10B, the display substrate in the conductive layer includes a first connecting line CL1, a second connecting line CL2, and a third connecting line CL3. Optionally, the first connecting line CL1, the second connecting line CL2, and the third connecting line CL3 are in a respective island of the plurality of islands Is. In one example depicted in FIG. 10B, the third connecting line CL3 spaces apart the first connecting line CL1 and the second connecting line CL2. The third connecting line CL3 may have various appropriate shapes. In one particular example, the third connecting line CL3 has pseudo H shape. As discussed further in details below, the first connecting line CL1 and the second connecting line CL2 are parts of a first voltage supply network (e.g., parts of a respective first voltage supply line of the plurality of first voltage supply lines VSL1). The third connecting line CL3 is a part of a second voltage supply network (e.g., a part of a respective second voltage supply line of the plurality of second voltage supply lines VSL2). The first connecting line CL1 and the second connecting line CL2 are configured to be provided with a first voltage supply signal. The third connecting line CL3 is configured to be provided with a second voltage supply signal.

Referring to FIG. 10A and FIG. 10C, the display substrate in the signal line layer includes a plurality of row connecting lines and a plurality of column connecting lines. An individual one of the plurality of row connecting lines and the plurality of column connecting lines is at least partially in an individual bridge of the plurality of bridges Br.

In some embodiments, the display substrate in the signal line layer includes a first row connecting line RCL1 at least partially in an individual bridge of the plurality of bridges Br, the first row connecting line RCL1 electrically connects the first connecting line CL1 in a respective island of the plurality of islands Is with an adjacent island of the plurality of islands Is in a first adjacent row (e.g., a previous row or a next row) and in a same column, for example, with a second connecting line CL2 in the adjacent island of the plurality of islands Is in the first adjacent row (e.g., the previous row or the next row) and in the same column.

In some embodiments, the display substrate in the signal line layer includes a second row connecting line RCL2 at least partially in an individual bridge of the plurality of bridges Br, the second row connecting line RCL2 electrically connects the second connecting line CL2 in a respective island of the plurality of islands Is with an adjacent island of the plurality of islands Is in a second adjacent row (e.g., a next row or a previous row) and in a same column, for example, with a first connecting line CL1 in the adjacent island of the plurality of islands Is in the second adjacent row (e.g., the next row or the previous row) and in the same column. The first adjacent row and the second adjacent row are two different rows on two different sides, along a column direction, of a present row having the respective island of the plurality of islands Is.

In some embodiments, the display substrate in the signal line layer includes a first column connecting line CCL1 at least partially in an individual bridge of the plurality of bridges Br, the first column connecting line CCL1 electrically connects the first connecting line CL1 in a respective island of the plurality of islands Is with an adjacent island of the plurality of islands Is in a first adjacent column (e.g., a previous column or a next column) and in a same row, for example, with a first connecting line CL1 in the adjacent island of the plurality of islands Is in the first adjacent column (e.g., the previous column or the next column) and in the same row.

In some embodiments, the display substrate in the signal line layer includes a second column connecting line CCL2 at least partially in an individual bridge of the plurality of bridges Br, the second column connecting line CCL2 electrically connects the second connecting line CL2 in a respective island of the plurality of islands Is with an adjacent island of the plurality of islands Is in a second adjacent column (e.g., a next column or a previous column) and in a same row, for example, with a second connecting line CL2 in the adjacent island of the plurality of islands Is in the second adjacent column (e.g., the next column or the previous column) and in the same row. The first adjacent column and the second adjacent column are two different columns on two different sides, along a row direction, of a present column having the respective island of the plurality of islands Is.

In some embodiments, the display substrate in the signal line layer includes a third row connecting line RCL3 at least partially in an individual bridge of the plurality of bridges Br, the third row connecting line RCL3 electrically connects the third connecting line CL3 in a respective island of the plurality of islands Is with an adjacent island of the plurality of islands Is in a first adjacent row (e.g., a previous row or a next row) and in a same column, for example, with a third connecting line CL3 in the adjacent island of the plurality of islands Is in the first adjacent row (e.g., the previous row or the next row) and in the same column.

In some embodiments, the display substrate in the signal line layer includes a fourth row connecting line RCL4 at least partially in an individual bridge of the plurality of bridges Br, the fourth row connecting line RCL4 electrically connects the third connecting line CL3 in a respective island of the plurality of islands Is with an adjacent island of the plurality of islands Is in a second adjacent row (e.g., a next row or a previous row) and in a same column, for example, with a third connecting line CL3 in the adjacent island of the plurality of islands Is in the second adjacent row (e.g., the next row or the previous row) and in the same column. The first adjacent row and the second adjacent row are two different rows on two different sides, along a column direction, of a present row having the respective island of the plurality of islands Is.

In some embodiments, the display substrate in the signal line layer includes a third column connecting line CCL3 at least partially in an individual bridge of the plurality of bridges Br, the third column connecting line CCL3 electrically connects the third connecting line CL3 in a respective island of the plurality of islands Is with an adjacent island of the plurality of islands Is in a first adjacent column (e.g., a previous column or a next column) and in a same row, for example, with a third connecting line CL3 in the adjacent island of the plurality of islands Is in the first adjacent column (e.g., the previous column or the next column) and in the same row.

In some embodiments, the display substrate in the signal line layer includes a fourth column connecting line CCL4 at least partially in an individual bridge of the plurality of bridges Br, the fourth column connecting line CCL4 electrically connects the third connecting line CL3 in a respective island of the plurality of islands Is with an adjacent island of the plurality of islands Is in a second adjacent column (e.g., a next column or a previous column) and in a same row, for example, with a third connecting line CL3 in the adjacent island of the plurality of islands Is in the second adjacent column (e.g., the next column or the previous column) and in the same row. The first adjacent column and the second adjacent column are two different columns on two different sides, along a row direction, of a present column having the respective island of the plurality of islands Is.

Referring to 10A and FIG. 10C, the display substrate in the signal line layer includes a fourth connecting line CL4 in a respective island of the plurality of islands Is. The fourth connecting line CL4 electrically connecting the first connecting line CL1 and the second connecting line CL2 in a same island of the plurality of islands Is.

Referring to FIG. 10A and FIG. 10C, the display substrate in the signal line layer includes an anode connecting pad ACP in a respective island of the plurality of islands Is. The anode connecting pad ACP electrically connects one or more anode with the third connecting line CL3, thereby providing the first voltage supply signal to the one or more anode.

Referring to FIG. 10A to FIG. 10D, the display substrate in the anode material layer in some embodiments includes one or more anode AD, a cathode connecting pad CDCP, and a cathode connecting line CDCL. The one or more anode AD, the cathode connecting pad CDCP, and the cathode connecting line CDCL are at least partially in a respective island of the plurality of islands Is. Optionally, the cathode connecting pad CDCP and the cathode connecting line CDCL are parts of a unitary structure. The cathode connecting pad CDCP and the cathode connecting line CDCL electrically connect the first connecting line CL1 to a cathode in the respective island, and electrically connect the second connecting line CL2 to the cathode in the respective island, thereby providing a second voltage supply signal to the cathode.

Referring to FIG. 10A to FIG. 10E, the display substrate includes the pixel definition layer PDL that defines a subpixel aperture. In some embodiments, the display substrate in the light emitting layer includes one or more light emitting blocks EL. An orthographic projection of the one or more light emitting blocks EL on a base substrate at least partially overlaps with an orthographic projection of the one or more anodes on a base substrate.

Referring to FIG. 10A to FIG. 10F, the display substrate in the cathode material layer includes a cathode CD in a respective island of the plurality of islands Is.

FIG. 12 illustrates a cross-sectional view along a B-B′ line in FIG. 10A. Referring to FIG. 12, and FIG. 10A to FIG. 10F, in some embodiments, the cathode connecting pad CDCP and the cathode connecting line CDCL is connected to (e.g., in direct contact with) the cathode CD. The cathode connecting pad CDCP is connected to the fourth connecting line CL4 through a via extending through the planarization layer PLN. The cathode connecting line CDCL is connected to the fourth connecting line CL4 through a via extending through the planarization layer PLN. The fourth connecting line CL4 is connected to the second connecting line CL2 through a via extending through the insulating layer IN. The fourth connecting line CL4 is connected to the first connecting line CL1 through a via extending through the insulating layer IN. The cathode CD is electrically connected to the first connecting line CL1 and is electrically connected to the second connecting line CL2, thereby receiving a second voltage supply signal from the first connecting line CL1 and the second connecting line CL2.

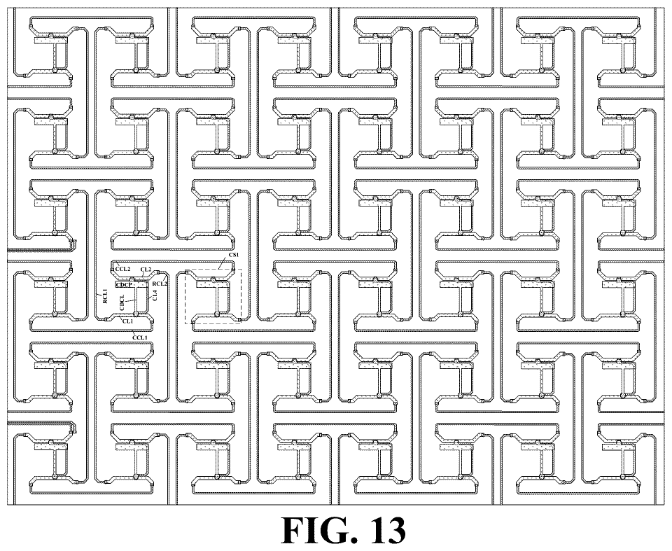

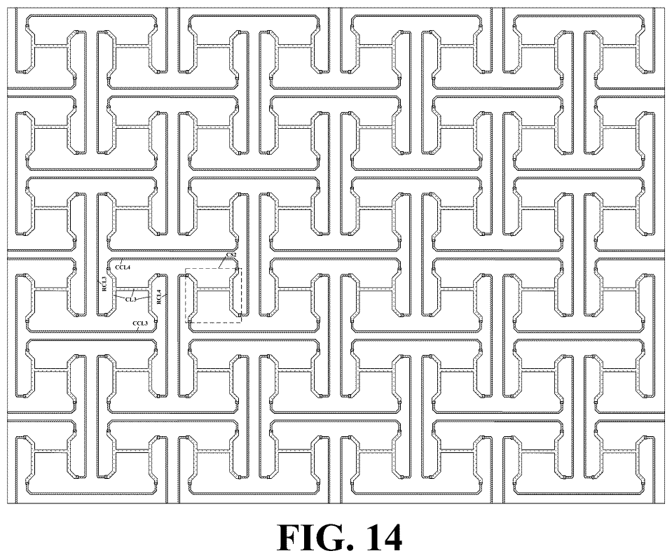

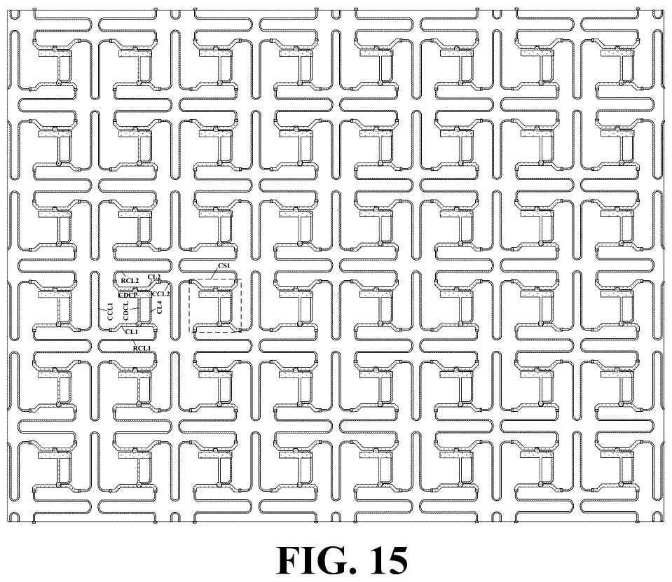

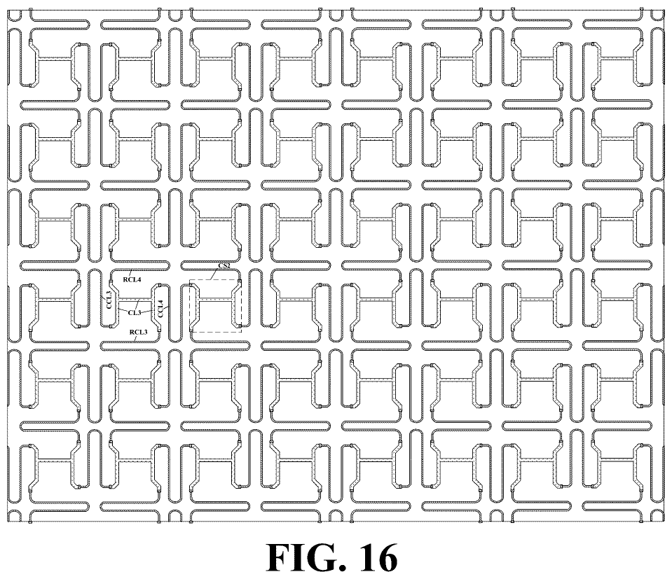

FIG. 13 illustrates a first voltage supply network in a display area in some embodiments according to the present disclosure. FIG. 14 illustrates a second voltage supply network in a display area in some embodiments according to the present disclosure. The voltage supply networks depicted in FIG. 13 and FIG. 14 correspond to those depicted in FIG. 9A to FIG. 9F. FIG. 15 illustrates a first voltage supply network in a display area in some embodiments according to the present disclosure. FIG. 16 illustrates a second voltage supply network in a display area in some embodiments according to the present disclosure. The voltage supply networks depicted in FIG. 15 and FIG. 16 correspond to those depicted in FIG. 10A to FIG. 10F. FIG. 9A to FIG. 9F, FIG. 10A to FIG. 10F, and FIG. 13 to FIG. 16 depict regions of the display substrate that are not directly adjacent to the peripheral area. For example, FIG. 9A to FIG. 9F, FIG. 10A to FIG. 10F, and FIG. 13 to FIG. 16 depict regions that are spaced apart from the peripheral area by at least one row of islands of the plurality of islands and spaced apart from the peripheral area by at least one column of islands of the plurality of islands. As used herein, a row of islands directly adjacent to the peripheral area is denoted as a border row, and a column of islands directly adjacent to the peripheral area is denoted as a border column.

Referring to FIG. 13 and FIG. 15, the first voltage supply network in some embodiments includes a plurality of first connecting structures CS1. Optionally, the plurality of first connecting structures CS1 are arranged in a first array of rows and columns. A respective first connecting structure of the plurality of first connecting structures CS1 in a region spaced apart from the peripheral area by at least a border row and at least a border column is connected to at least one of a first row connecting line RCL1, a second row connecting line RCL2, a first column connecting line CCL1, or a second column connecting line CCL2.

In some embodiments, the first row connecting line RCL1 connects a respective first connecting structure of the plurality of first connecting structures CS1 with a first connecting structure in a first adjacent row (e.g., a previous row or a next row) and in a same column together. In some embodiments, the second row connecting line RCL2 connects the respective first connecting structure with a first connecting structure in a second adjacent row (e.g., a next row or a previous row) and in a same column together. The first adjacent row and the second adjacent row are two different rows on two different sides, along a column direction, of a present row having the respective island of the plurality of islands Is.

In some embodiments, the first column connecting line CCL1 connects the respective first connecting structure with a first connecting structure in a first adjacent column (e.g., a previous column or a next column) and in a same row together. In some embodiments, the second column connecting line CCL2 connects the respective first connecting structure with a first connecting structure in a second adjacent column (e.g., a next column or a previous column) and in a same row together. The first adjacent column and the second adjacent column are two different columns on two different sides, along a row direction, of a present column having the respective island of the plurality of islands Is.

In some embodiments, the respective first connecting structure includes the first connecting line CL1 and the second connecting line CL2 electrically connected to each other. The first connecting line CL1 is connected to the first row connecting line RCL1 and the first column connecting line CCL1. The second connecting line CL2 is connected to the second row connecting line RCL2 and the second column connecting line CCL2. The respective first connecting structure further includes one or more connecting lines in a layer different from the first connecting line CL1 and the second connecting line CL2. Optionally, the respective first connecting structure further includes a fourth connecting line CL4 connecting the first connecting line CL1 and the second connecting line CL2 together. In one example, the first connecting line CL1 and the second connecting line CL2 are in the conductive layer, and the fourth connecting line CL4 is in the signal line layer. Optionally, the respective first connecting structure further includes a structure in the anode material layer that connects the first connecting line CL1 and the second connecting line CL2 together. In one example, the structure in the anode material layer connecting the first connecting line CL1 and the second connecting line CL2 together includes a cathode connecting line CDCL and a cathode connecting pad CDCP. The structure in the anode material layer connecting the first connecting line CL1 and the second connecting line CL2 together is further connected to the cathode.

In one example, the first connecting line CL1 and the second connecting line CL2 are in the conductive layer. The first row connecting line RCL1, the second row connecting line RCL2, the first column connecting line CCL1, the second column connecting line CCL2, and the fourth connecting line CL4 are in the signal line layer. The cathode connecting line CDCL and the cathode connecting pad CDCP are in the anode material layer.

Each of the first connecting line CL1, the second connecting line CL2, the fourth connecting line CL4, the cathode connecting line CDCL and the cathode connecting pad CDCP is at least partially in the respective island of the plurality of islands. Each of the first row connecting line RCL1, the second row connecting line RCL2, the first column connecting line CCL1, and the second column connecting line CCL2 is at least partially in an individual bridge of the plurality of bridges. The first row connecting line RCL1, the second row connecting line RCL2, the first column connecting line CCL1, and the second column connecting line CCL2 are in four different bridges of the plurality of bridges. The four different bridges are connected to the respective island, respectively.

Referring to FIG. 14 and FIG. 16, the second voltage supply network in some embodiments includes a plurality of second connecting structures CS2. Optionally, the plurality of second connecting structures CS2 are arranged in a second array of rows and columns. A respective second connecting structure of the plurality of second connecting structures CS2 in a region spaced apart from the peripheral area by at least a border row and at least a border column is connected to at least one of a third row connecting line RCL3, a fourth row connecting line RCL4, a third column connecting line CCL3, or a fourth column connecting line CCL4.

In some embodiments, the third row connecting line RCL3 connects a respective second connecting structure of the plurality of second connecting structures CS2 with a second connecting structure in a first adjacent row (e.g., a previous row or a next row) and in a same column together. In some embodiments, the fourth row connecting line RCL4 connects the respective second connecting structure with a connecting structure in a second adjacent row (e.g., a next row or a previous row) and in a same column together. The first adjacent row and the second adjacent row are two different rows on two different sides, along a column direction, of a present row having the respective island of the plurality of islands Is.

In some embodiments, the third column connecting line CCL3 connects the respective second connecting structure with a connecting structure in a first adjacent column (e.g., a previous column or a next column) and in a same row together. In some embodiments, the fourth column connecting line CCL4 connects the respective second connecting structure with a connecting structure in the first adjacent column (e.g., the previous column or the next column) and in the same row together. The first adjacent column and the second adjacent column are two different columns on two different sides, along a row direction, of a present column having the respective island of the plurality of islands Is.

In some embodiments, the respective second connecting structure includes the third connecting line CL3. The third connecting line CL3 is connected to the third row connecting line RCL3, the fourth row connecting line RCL4, the third column connecting line CCL3, and the fourth column connecting line CCL4.

In one example, the third connecting line CL3 is in the conductive layer. The third row connecting line RCL3, the fourth row connecting line RCL4, the third column connecting line CCL3, and the fourth column connecting line CCL4 are in the signal line layer.

The third connecting line CL3 is at least partially in the respective island of the plurality of islands. Each of the third row connecting line RCL3, the fourth row connecting line RCL4, the third column connecting line CCL3, and the fourth column connecting line CCL4 is at least partially in an individual bridge of the plurality of bridges. The third row connecting line RCL3, the fourth row connecting line RCL4, the third column connecting line CCL3, and the fourth column connecting line CCL4 are in four different bridges of the plurality of bridges. The four different bridges are connected to the respective island, respectively.

In one example, the first row connecting line RCL1 and the third row connecting line RCL3 are in a same first bridge. In another example, the second row connecting line RCL2 and the fourth row connecting line RCL4 are in a same second bridge. In another example, the first column connecting line CCL1 and the third column connecting line CCL3 are in a same third bridge. In another example, the second column connecting line CCL2 and the fourth column connecting line CCL4 are in a same fourth bridge.

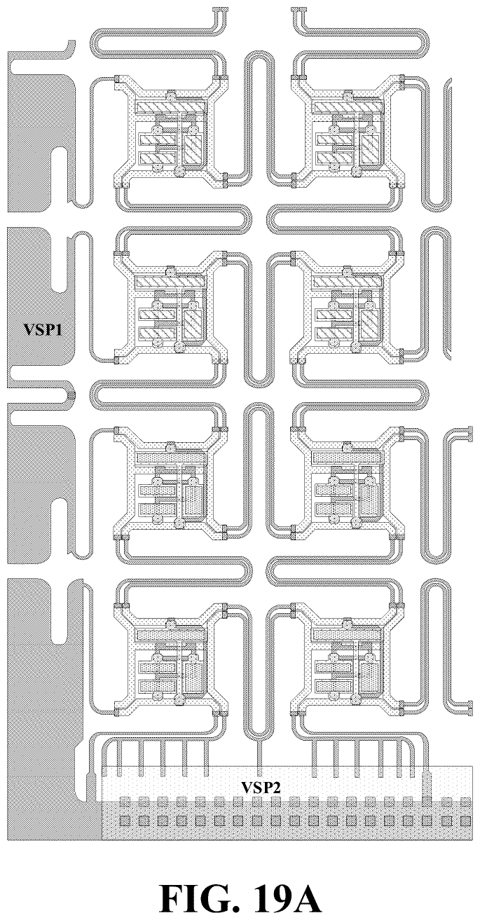

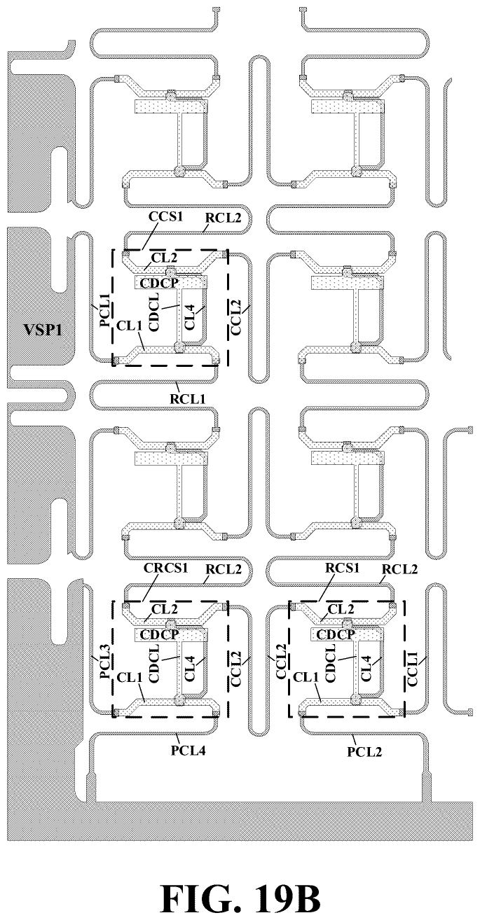

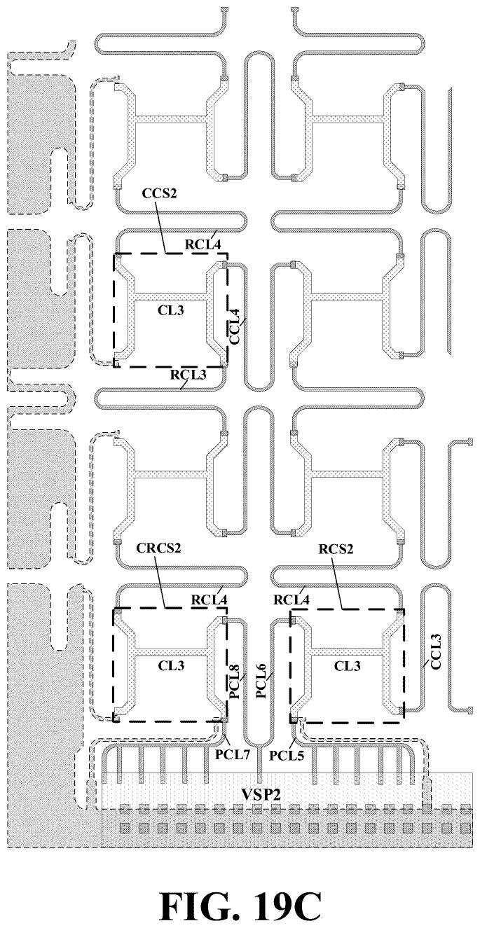

FIG. 17 is a schematic diagram illustrating a region of a display substrate between a display area and a peripheral area of the display substrate in some embodiments according to the present disclosure. FIG. 18A illustrates the structure of a border row and a border column in a display substrate in some embodiments according to the present disclosure. FIG. 18B illustrate the structure of a portion of a first voltage supply network in a border row and a border column in a display substrate in some embodiments according to the present disclosure. FIG. 18C illustrate the structure of a portion of a second voltage supply network in a border row and a border column in a display substrate in some embodiments according to the present disclosure. FIG. 19A illustrates the structure of a border row and a border column in a display substrate in some embodiments according to the present disclosure. FIG. 19B illustrate the structure of a portion of a first voltage supply network in a border row and a border column in a display substrate in some embodiments according to the present disclosure. FIG. 19C illustrate the structure of a portion of a second voltage supply network in a border row and a border column in a display substrate in some embodiments according to the present disclosure.

Referring to FIG. 18A, FIG. 19A, FIG. 18B, and FIG. 19B, the first voltage supply network in some embodiments includes a first column of connecting structures directly adjacent to, and connected to, the at least one first voltage supply pad VSP1. A respective first column connecting structure CCS1 in the first column of connecting structures directly adjacent to, and connected to, the at least one first voltage supply pad VSP1 is denoted in FIG. 18B and FIG. 19B. In some embodiments, the first voltage supply network includes a first pad connecting line PCL1. The first pad connecting line PCL1 connects the respective first column connecting structure CCS1 with the at least one first voltage supply pad VSP1 (instead of connecting with an adjacent connecting structure). For example, the first pad connecting line PCL1 connects the respective first column connecting structure CCS1 with a first voltage supply pad in the second sub-area PA2 depicted in FIG. 3.

In one example depicted in FIG. 18B, the first pad connecting line PCL1 connects the second connecting line CL2 in the respective first column connecting structure CCS1 to the at least one first voltage supply pad VSP1.

In another example depicted in FIG. 19B, the first pad connecting line PCL1 connects the first connecting line CL1 in the respective first column connecting structure CCS1 to the at least one first voltage supply pad VSP1.

Referring to FIG. 18B and FIG. 19B, in some embodiments, a first row connecting line RCL1 connects the respective first column connecting structure CCS1 with a column connecting structure in a first adjacent row (e.g., a previous row or a next row) and in a same column together. In some embodiments, the second row connecting line RCL2 connects the respective first column connecting structure CCS1 with a column connecting structure in a second adjacent row (e.g., a next row or a previous row) and in a same column together. The first adjacent row and the second adjacent row are two different rows on two different sides, along a column direction, of a present row having the respective first column connecting structure CCS1.

Referring to FIG. 18B, in one example, the first voltage supply network in some embodiments includes a first column connecting line CCL1 connecting the respective first column connecting structure CCS1 with a first connecting structure in an adjacent column (e.g., a next column) and in a same row together. Optionally, the first column connecting line CCL1 connects a first connecting line CL1 in the respective first column connecting structure CCS1 with a first connecting line CL1 in the first connecting structure in the adjacent column.

Referring to FIG. 19B, in another example, the first voltage supply network in some embodiments includes a second column connecting line CCL2 connecting the respective first column connecting structure CCS1 with a first connecting structure in an adjacent column (e.g., a next column) and in a same row together. Optionally, the second column connecting line CCL2 connects a second connecting line CL2 in the respective first column connecting structure CCS1 with a second connecting line CL2 in the first connecting structure in the adjacent column.

In some embodiments, the respective first column connecting structure CCS1 includes the first connecting line CL1 and the second connecting line CL2 electrically connected to each other. At least one of the first connecting line CL1 and the second connecting line CL2 is connected to the first pad connecting line PCL1. The first connecting line CL1 is connected to the first row connecting line RCL1. The second connecting line CL2 is connected to the second row connecting line RCL2. The respective first column connecting structure CCS1 further includes one or more connecting lines in a layer different from the first connecting line CL1 and the second connecting line CL2. Optionally, the respective first column connecting structure CCS1 further includes a fourth connecting line CL4 connecting the first connecting line CL1 and the second connecting line CL2 together. In one example, the first connecting line CL1 and the second connecting line CL2 are in the conductive layer, and the fourth connecting line CL4 is in the signal line layer. Optionally, the respective first column connecting structure CCS1 further includes a structure in the anode material layer that connects the first connecting line CL1 and the second connecting line CL2 together. In one example, the structure in the anode material layer connecting the first connecting line CL1 and the second connecting line CL2 together includes a cathode connecting line CDCL and a cathode connecting pad CDCP. The structure in the anode material layer connecting the first connecting line CL1 and the second connecting line CL2 together is further connected to the cathode.

Referring to FIG. 18A, FIG. 19A, FIG. 18B, and FIG. 19B, the first voltage supply network in some embodiments includes a first row of connecting structures directly adjacent to, and connected to, the at least one first voltage supply pad VSP1. A respective first row connecting structure RCS1 in the first row of connecting structures directly adjacent to, and connected to, the at least one first voltage supply pad VSP1 is denoted in FIG. 18B and FIG. 19B. In some embodiments, the first voltage supply network includes a second pad connecting line PCL2. The second pad connecting line PCL2 connects the respective first row connecting structure RCS1 with the at least one first voltage supply pad VSP1 (instead of connecting with an adjacent connecting structure). For example, the second pad connecting line PCL2 connects the respective first row connecting structure RCS1 with a first voltage supply pad in the first sub-area PA1 depicted in FIG. 3.

In one example depicted in FIG. 18B, the second pad connecting line PCL2 connects the second connecting line CL2 in the respective first row connecting structure RCS1 to the at least one first voltage supply pad VSP1.

In another example depicted in FIG. 19B, the second pad connecting line PCL2 connects the first connecting line CL1 in the respective first row connecting structure RCS1 to the at least one first voltage supply pad VSP1.

Referring to FIG. 18B and FIG. 19B, in some embodiments, a first column connecting line CCL1 connects the respective first row connecting structure RCS1 with a row connecting structure in a first adjacent column (e.g., a previous column or a next column) and in a same row together. In some embodiments, the second column connecting line CCL2 connects the respective first row connecting structure RCS1 with a column connecting structure in a second adjacent column (e.g., a next column or a previous column) and in a same row together. The first adjacent column and the second adjacent column are two different columns on two different sides, along a row direction, of a present column having the respective first row connecting structure RCS1.

Referring to FIG. 18B, in one example, the first voltage supply network in some embodiments includes a first row connecting line RCL1 connecting the respective first row connecting structure RCS1 with a first connecting structure in an adjacent row (e.g., a previous row) and in a same column together. Optionally, the first row connecting line RCL1 connects a first connecting line CL1 in the respective first row connecting structure RCS1 with a second connecting line CL2 in the first connecting structure in the adjacent row.

Referring to FIG. 19B, in another example, the first voltage supply network in some embodiments includes a second row connecting line RCL2 connecting the respective first row connecting structure RCS1 with a first connecting structure in an adjacent row (e.g., a previous row) and in a same column together. Optionally, the second row connecting line RCL2 connects a second connecting line CL2 in the respective first row connecting structure RCS1 with a first connecting line CL1 in the first connecting structure in the adjacent row.

In some embodiments, the respective first row connecting structure RCS1 includes the first connecting line CL1 and the second connecting line CL2 electrically connected to each other. At least one of the first connecting line CL1 and the second connecting line CL2 is connected to the second pad connecting line PCL2.

The first connecting line CL1 is connected to the first column connecting line CCL1. The second connecting line CL2 is connected to the second column connecting line CCL2.

The respective first row connecting structure RCS1 further includes one or more connecting lines in a layer different from the first connecting line CL1 and the second connecting line CL2. Optionally, the respective first row connecting structure RCS1 further includes a fourth connecting line CL4 connecting the first connecting line CL1 and the second connecting line CL2 together. In one example, the first connecting line CL1 and the second connecting line CL2 are in the conductive layer, and the fourth connecting line CL4 is in the signal line layer. Optionally, the respective first row connecting structure RCS1 further includes a structure in the anode material layer that connects the first connecting line CL1 and the second connecting line CL2 together. In one example, the structure in the anode material layer connecting the first connecting line CL1 and the second connecting line CL2 together includes a cathode connecting line CDCL and a cathode connecting pad CDCP. The structure in the anode material layer connecting the first connecting line CL1 and the second connecting line CL2 together is further connected to the cathode.

Referring to FIG. 18A, FIG. 19A, FIG. 18B, and FIG. 19B, the first voltage supply network in some embodiments includes a first corner connecting structure CRCS1 directly adjacent to, and connected to, the at least one first voltage supply pad VSP1. In some embodiments, the first voltage supply network includes a third pad connecting line PCL3 and a fourth pad connecting line PCL4. The third pad connecting line PCL3 connects the first corner connecting structure CRCS1 with the at least one first voltage supply pad VSP1 (instead of connecting with an adjacent connecting structure). For example, the third pad connecting line PCL3 connects the first corner connecting structure CRCS1 with a first voltage supply pad in the second sub-area PA2 depicted in FIG. 3. The fourth pad connecting line PCL4 connects the first corner connecting structure CRCS1 with the at least one first voltage supply pad VSP1 (instead of connecting with an adjacent connecting structure). For example, the fourth pad connecting line PCL4 connects the first corner connecting structure CRCS1 with a first voltage supply pad in the first sub-area PA1 depicted in FIG. 3.

In one example depicted in FIG. 18B, the third pad connecting line PCL3 connects the second connecting line CL2 in the first corner connecting structure CRCS1 to the at least one first voltage supply pad VSP1. The fourth pad connecting line PCL4 connects the second connecting line CL2 in the first corner connecting structure CRCS1 to the at least one first voltage supply pad VSP1. A first row connecting line RCL1 connects the first corner connecting structure CRCS1 with a column connecting structure in an adjacent row (e.g., a previous row) and in a same column together. A first column connecting line CCL1 connects the first corner connecting structure CRCS1 with a first connecting structure in an adjacent column (e.g., a next column) and in a same row together. Optionally, the first column connecting line CCL1 connects a first connecting line CL1 in the first corner connecting structure CRCS1 with a first connecting line CL1 in the first connecting structure in the adjacent column.

In another example depicted in FIG. 19B, the third pad connecting line PCL3 connects the first connecting line CL1 in the first corner connecting structure CRCS1 to the at least one first voltage supply pad VSP1. The fourth pad connecting line PCL4 connects the first connecting line CL1 in the first corner connecting structure CRCS1 to the at least one first voltage supply pad VSP1. A second row connecting line RCL2 connects the first corner connecting structure CRCS1 with a column connecting structure in an adjacent row (e.g., a previous row) and in a same column together. A second column connecting line CCL2 connects the first corner connecting structure CRCS1 with a first connecting structure in an adjacent column (e.g., a next column) and in a same row together. Optionally, the second column connecting line CCL2 connects a second connecting line CL2 in the first corner connecting structure CRCS1 with a second connecting line CL2 in the first connecting structure in the adjacent column.

In some embodiments, the first corner connecting structure CRCS1 includes the first connecting line CL1 and the second connecting line CL2 electrically connected to each other. At least one of the first connecting line CL1 and the second connecting line CL2 is connected to the third pad connecting line PCL3 and/or the fourth pad connecting line PCL4. The first corner connecting structure CRCS1 further includes one or more connecting lines in a layer different from the first connecting line CL1 and the second connecting line CL2. Optionally, the first corner connecting structure CRCS1 further includes a fourth connecting line CL4 connecting the first connecting line CL1 and the second connecting line CL2 together. In one example, the first connecting line CL1 and the second connecting line CL2 are in the conductive layer, and the fourth connecting line CL4 is in the signal line layer. Optionally, the first corner connecting structure CRCS1 further includes a structure in the anode material layer that connects the first connecting line CL1 and the second connecting line CL2 together. In one example, the structure in the anode material layer connecting the first connecting line CL1 and the second connecting line CL2 together includes a cathode connecting line CDCL and a cathode connecting pad CDCP. The structure in the anode material layer connecting the first connecting line CL1 and the second connecting line CL2 together is further connected to the cathode.

Referring to FIG. 18A, FIG. 19A, FIG. 18C, and FIG. 19C, the second voltage supply network in some embodiments includes a second column of connecting structures directly adjacent to the at least one second voltage supply pad VSP2. A respective second column connecting structure CCS2 in the second column of connecting structures directly adjacent to the at least one second voltage supply pad VSP2 is denoted in FIG. 18C and FIG. 19C. In some embodiments, the respective second column connecting structure CCS2 is connected to at least one of a third row connecting line RCL3 and a fourth row connecting line RCL4. In one example, the respective second column connecting structure CCS2 is further connected to a third column connecting line CCL3 (FIG. 18C). In another example, the respective second column connecting structure CCS2 is further connected to a fourth column connecting line CCL4 (FIG. 19C).

In some embodiments, the third row connecting line RCL3 connects the respective second column connecting structure CCS2 with a connecting structure in a first adjacent row (e.g., a previous row or a next row) and in a same column together. In some embodiments, the fourth row connecting line RCL4 connects the respective second column connecting structure CCS2 with a connecting structure in a second adjacent row (e.g., a next row or a previous row) and in a same column together. The first adjacent row and the second adjacent row are two different rows on two different sides, along a column direction, of a present row having the respective island of the plurality of islands Is.

Referring to FIG. 18C, the third column connecting line CCL3 connects the respective second column connecting structure CCS2 with a connecting structure in an adjacent column (e.g., a next column) and in a same row together.

Referring to FIG. 19C, the fourth column connecting line CCL4 connects the respective second column connecting structure CCS2 with a connecting structure in an adjacent column (e.g., a next column) and in the same row together.

In some embodiments, the respective second column connecting structure CCS2 includes the third connecting line CL3. The third connecting line CL3 is connected to the third row connecting line RCL3 and the fourth row connecting line RCL4. Referring to FIG. 18C, the third connecting line CL3 is connected to the third column connecting line CCL3. Referring to FIG. 19C, the third connecting line CL3 is connected to the fourth column connecting line CCL4.

Referring to FIG. 18A, FIG. 19A, FIG. 18C, and FIG. 19C, the second voltage supply network in some embodiments includes a second row of connecting structures directly adjacent to, and connected to, the at least one second voltage supply pad VSP2. A respective second row connecting structure RCS2 in the second row of connecting structures directly adjacent to the at least one second voltage supply pad VSP2 is denoted in FIG. 18C and FIG. 19C. In some embodiments, the first voltage supply network includes a fifth pad connecting line PCL5 and a sixth pad connecting line PCL6.

The fifth pad connecting line PCL5 connects the respective second row connecting structure RCS2 with the at least one second voltage supply pad VSP2 (instead of connecting with an adjacent connecting structure). For example, the fifth pad connecting line PCL5 connects the respective second row connecting structure RCS2 with a first voltage supply pad in the first sub-area PA1 depicted in FIG. 3.

The sixth pad connecting line PCL6 connects the respective second row connecting structure RCS2 with the at least one second voltage supply pad VSP2 (instead of connecting with an adjacent connecting structure). For example, the sixth pad connecting line PCL6 connects the respective second row connecting structure RCS2 with a first voltage supply pad in the first sub-area PA1 depicted in FIG. 3.

In one example depicted in FIG. 18C, a third row connecting line RCL3 connects the respective second row connecting structure RCS2 with a second connecting structure in an adjacent row (e.g., a previous row) and in a same column together. A fourth column connecting line CCL4 connects the respective second row connecting structure RCS2 with a connecting structure in an adjacent column (e.g., a previous column or a next column) and in a same row together.

In another example depicted in FIG. 19C, a fourth row connecting line RCL4 connects the respective second row connecting structure RCS2 with a second connecting structure in an adjacent row (e.g., a previous row) and in a same column together. A third column connecting line CCL3 connects the respective second row connecting structure RCS2 with a connecting structure in an adjacent column (e.g., a previous column or a next column) and in a same row together.

Referring to FIG. 18A, FIG. 19A, FIG. 18C, and FIG. 19C, the second voltage supply network in some embodiments includes a second corner connecting structure CRCS2 directly adjacent to, and connected to, the at least one second voltage supply pad VSP2. In some embodiments, the first voltage supply network includes a seventh pad connecting line PCL7 and an eighth pad connecting line PCL8.

The seventh pad connecting line PCL7 connects the second corner connecting structure CRCS2 with the at least one second voltage supply pad VSP2 (instead of connecting with an adjacent connecting structure). For example, the seventh pad connecting line PCL7 connects the second corner connecting structure CRCS2 with a first voltage supply pad in the first sub-area PA1 depicted in FIG. 3.

The eighth pad connecting line PCL8 connects the second corner connecting structure CRCS2 with the at least one second voltage supply pad VSP2 (instead of connecting with an adjacent connecting structure). For example, the eighth pad connecting line PCL8 connects the second corner connecting structure CRCS2 with a first voltage supply pad in the first sub-area PA1 depicted in FIG. 3.

In one example depicted in FIG. 18C, a third row connecting line RCL3 connects the second corner connecting structure CRCS2 with a second connecting structure in an adjacent row (e.g., a previous row) and in a same column together.

In another example depicted in FIG. 19C, a fourth row connecting line RCL4 connects the second corner connecting structure CRCS2 with a second connecting structure in an adjacent row (e.g., a previous row) and in a same column together.

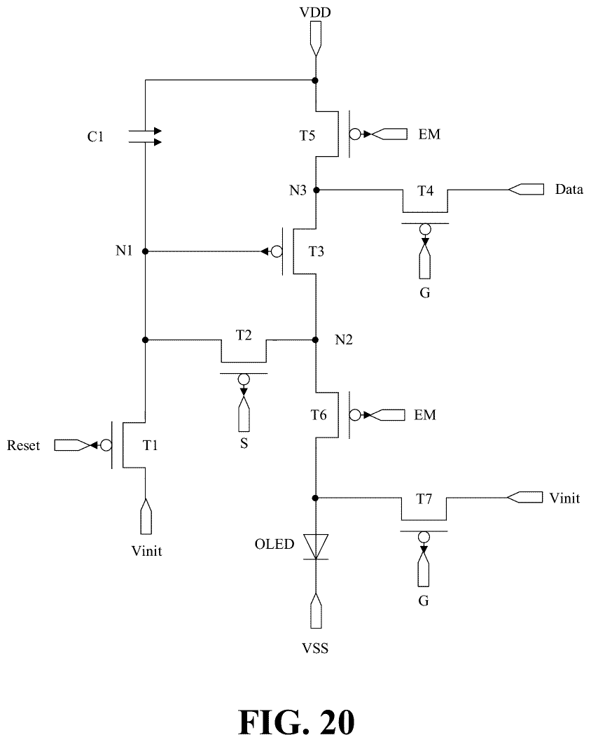

Various appropriate display elements may be used in the present disclosure. FIG. 9A to FIG. 9F, and FIG. 10A to FIG. 10F illustrate a passive matrix light emitting diode as the display element. However, an active matrix light emitting diode instead of the passive matrix light emitting diode may be implemented according to the present disclosure. FIG. 20 is a circuit diagram illustrating the structure of a pixel driving circuit for driving an active matrix light emitting diode in some embodiments according to the present disclosure. Referring to FIG. 20, in some embodiments, the pixel driving circuit includes seven transistors (first transistor T1 to seventh transistor T7), a capacitor C, and eight signal terminals including a data signal terminal Data, a control signal terminal G, a scan signal terminal S, a reset signal terminal Reset, a light emitting signal terminal EM, an initial signal terminal Vinit, a first power supply terminal VDD (configured to receive the second voltage supply signal according to the present disclosure), and a second power supply terminal VSS (configured to receive the first voltage supply signal according to the present disclosure).

In some embodiments, a first electrode plate of the capacitor C is connected to the first power supply terminal VDD and a second electrode plate of the capacitor C is connected to a first node N1. A gate electrode of the first transistor T1 is connected to the reset signal terminal Reset, a first electrode of the first transistor T1 is connected to the initial signal terminal Vinit, and a second electrode of the first transistor is connected to the first node N1; a gate electrode of the second transistor T2 is connected to the scan signal terminal S, a first electrode of the second transistor T2 is connected to the first node N1, and a second electrode of the second transistor T2 is connected to a second node N2; a gate electrode of the third transistor T3 is connected to the first node N1, a first electrode of the third transistor T3 is connected to the second node N2, and a second electrode of the third transistor T3 is connected to a third node N3; a gate electrode of the fourth transistor T4 is connected to the control signal terminal G, a first electrode of the fourth transistor T4 is connected to the data signal terminal Data, and a second electrode of the fourth transistor T4 is connected to the third node N3; a gate electrode of the fifth transistor T5 is connected to the light emitting signal terminal EM, a first electrode of the fifth transistor T5 is connected to the first power supply terminal VDD, a second electrode of the fifth transistor T5 is connected to the third node N3; a gate electrode of the sixth transistor T6 is connected to the light emitting signal terminal EM, a first electrode of the sixth transistor T6 is connected to the second node N2, a second electrode of the sixth transistor T6 is connected to an anode of a respective light emitting element driven by the respective pixel driving circuit; a gate electrode of the seventh transistor T7 is connected to the control signal terminal G, a first electrode of the seventh transistor T7 is connected to the initial signal terminal Vinit, a second electrode of the seventh transistor T7 is connected to the anode of the respective light emitting element, and a second electrode of the respective light emitting element is connected to the second power supply terminal VSS. In some embodiments, the first transistor T1 may be referred to as a reset transistor, and when a valid level signal is input at the reset signal terminal Reset, the first transistor T1 transmits an initialization voltage to the first node N1 to initialize the charge of the first node N1.

In another aspect, the present invention provides a display apparatus, including the display substrate described herein or fabricated by a method described herein, and one or more integrated circuits connected to the display substrate. Examples of appropriate display apparatuses include, but are not limited to, an electronic paper, a mobile phone, a tablet computer, a television, a monitor, a notebook computer, a digital album, a GPS, etc. Optionally, the display apparatus is an organic light emitting diode display apparatus. Optionally, the display apparatus is a micro light emitting diode display apparatus. Optionally, the display apparatus is a mini light emitting diode display apparatus.

In another aspect, the present disclosure provides a method of fabricating a display substrate. In some embodiments, the method includes forming a plurality of islands and a plurality of bridges connecting the plurality of islands. Optionally, the method includes forming a first voltage supply network. Optionally, forming the first voltage supply network includes forming a plurality of first connecting structures in a display area of the display substrate, forming a first row connecting line, forming a second row connecting line, forming a first column connecting line, and forming a second column connecting line. Optionally, a respective first connecting structure of the plurality of first connecting structures is formed to be connected by the first row connecting line, the second row connecting line, the first column connecting line, and the second column connecting line, to four adjacent first connecting structures, respectively. Optionally, the first row connecting line, the second row connecting line, the first column connecting line, and the second column connecting line are formed in four different bridges of the plurality of bridges.

The foregoing description of the embodiments of the invention has been presented for purposes of illustration and description. It is not intended to be exhaustive or to limit the invention to the precise form or to exemplary embodiments disclosed. Accordingly, the foregoing description should be regarded as illustrative rather than restrictive. Obviously, many modifications and variations will be apparent to practitioners skilled in this art. The embodiments are chosen and described in order to explain the principles of the invention and its best mode practical application, thereby to enable persons skilled in the art to understand the invention for various embodiments and with various modifications as are suited to the particular use or implementation contemplated. It is intended that the scope of the invention be defined by the claims appended hereto and their equivalents in which all terms are meant in their broadest reasonable sense unless otherwise indicated. Therefore, the term “the invention”, “the present invention” or the like does not necessarily limit the claim scope to a specific embodiment, and the reference to exemplary embodiments of the invention does not imply a limitation on the invention, and no such limitation is to be inferred. The invention is limited only by the spirit and scope of the appended claims. Moreover, these claims may refer to use “first”, “second”, etc. following with noun or element. Such terms should be understood as a nomenclature and should not be construed as giving the limitation on the number of the elements modified by such nomenclature unless specific number has been given. Any advantages and benefits described may not apply to all embodiments of the invention. It should be appreciated that variations may be made in the embodiments described by persons skilled in the art without departing from the scope of the present invention as defined by the following claims. Moreover, no element and component in the present disclosure is intended to be dedicated to the public regardless of whether the element or component is explicitly recited in the following claims.

1. A display substrate, comprising a plurality of islands and a plurality of bridges connecting the plurality of islands;
wherein the display substrate comprises a first voltage supply network;
the first voltage supply network comprises a plurality of first connecting structures in a display area of the display substrate, a first row connecting line, a second row connecting line, a first column connecting line, and a second column connecting line;
a respective first connecting structure of the plurality of first connecting structures is connected by the first row connecting line, the second row connecting line, the first column connecting line, and the second column connecting line, to four adjacent first connecting structures, respectively;
the first row connecting line, the second row connecting line, the first column connecting line, and the second column connecting line are in four different bridges of the plurality of bridges.

2. The display substrate of claim 1, wherein the first row connecting line connects the respective first connecting structure with a first connecting structure in a first adjacent row and in a same column together;
the second row connecting line connects the respective first connecting structure with a first connecting structure in a second adjacent row and in a same column together; and
the first adjacent row and the second adjacent row are two different rows on two different sides, along a column direction, of a present row having the respective first connecting structure.

3. The display substrate of claim 1, wherein the first column connecting line connects the respective first connecting structure with a first connecting structure in a first adjacent column and in a same row together;
the second column connecting line connects the respective first connecting structure with a first connecting structure in a second adjacent column and in a same row together; and
the first adjacent column and the second adjacent column are two different columns on two different sides, along a row direction, of a present column having the respective first connecting structure.

4. The display substrate of claim 1, wherein the respective first connecting structure comprises a first connecting line and a second connecting line electrically connected to each other;
the first connecting line is connected to the first row connecting line and the first column connecting line; and
the second connecting line is connected to the second row connecting line and the second column connecting line.

5. The display substrate of claim 4, wherein the respective first connecting structure further includes one or more connecting lines in a layer different from the first connecting line and the second connecting line.

6. The display substrate of claim 5, wherein the one or more connecting lines includes a fourth connecting line connecting the first connecting line and the second connecting line together;
the first connecting line and the second connecting line are in a conductive layer; and
the fourth connecting line is in a signal line layer.

7. The display substrate of claim 5, wherein the one or more connecting lines includes a cathode connecting line and a cathode connecting pad connecting the first connecting line and the second connecting line together; and
at least one of the cathode connecting line and the cathode connecting pad is further connected to a cathode.

8. The display substrate of claim 1, further comprising:
at least one first voltage supply pad in a peripheral area of the display substrate;
a first column of connecting structures directly adjacent to, and connected to, the at least one first voltage supply pad; and
a first pad connecting line connecting a respective first column connecting structure in the first column of connecting structures with the at least one first voltage supply pad.

9. The display substrate of claim 1, further comprising:
at least one first voltage supply pad in a peripheral area of the display substrate;
a first row of connecting structures directly adjacent to, and connected to, the at least one first voltage supply pad; and
a second pad connecting line connecting a respective first row connecting structure in the first row of connecting structures with the at least one first voltage supply pad.

10. The display substrate of claim 1, further comprising:
at least one first voltage supply pad in a peripheral area of the display substrate;
a first corner connecting structure directly adjacent to, and connected to, the at least one first voltage supply pad;
a third pad connecting line connecting the first corner connecting structure with the at least one first voltage supply pad; and
a fourth pad connecting line connecting the first corner connecting structure with the at least one first voltage supply pad.

11. The display substrate of claim 1, further comprising a second voltage supply network;
wherein the second voltage supply network comprises a plurality of second connecting structures in a display area of the display substrate, a third row connecting line, a fourth row connecting line, a third column connecting line, and a fourth column connecting line;
a respective second connecting structure of the plurality of second connecting structures is connected by the third row connecting line, the fourth row connecting line, the third column connecting line, and the fourth column connecting line, to four adjacent second connecting structures, respectively;
the third row connecting line, the fourth row connecting line, the third column connecting line, and the fourth column connecting line are in the four different bridges.

12. The display substrate of claim 11, wherein the third row connecting line connects the respective second connecting structure with a second connecting structure in a first adjacent row and in a same column together;
the fourth row connecting line connects the respective second connecting structure with a connecting structure in a second adjacent row and in a same column together;
the first adjacent row and the second adjacent row are two different rows on two different sides, along a column direction, of a present row having the respective second connecting structure.

13. The display substrate of claim 11, wherein the third column connecting line connects the respective second connecting structure with a connecting structure in a first adjacent column and in a same row together;
the fourth column connecting line connects the respective second connecting structure with a connecting structure in a second adjacent column and in the same row together; and
the first adjacent column and the second adjacent column are two different columns on two different sides, along a row direction, of a present column having the respective second connecting structure.

14. The display substrate of claim 11, wherein the respective second connecting structure comprises a third connecting line in a conductive layer; and
the third row connecting line, the fourth row connecting line, the third column connecting line, and the fourth column connecting line are in a signal line layer.

15. The display substrate of claim 11, wherein the first row connecting line and the third row connecting line are in a same first bridge;
the second row connecting line and the fourth row connecting line are in a same second bridge;
the first column connecting line and the third column connecting line are in a same third bridge; and
the second column connecting line and the fourth column connecting line are in a same fourth bridge.

16. The display substrate of claim 11, further comprising:
at least one second voltage supply pad in a peripheral area of the display substrate;
a second row of connecting structures directly adjacent to, and connected to, the at least one second voltage supply pad;
a fifth pad connecting line connecting a respective second row connecting structure in the second row of connecting structures with the at least one second voltage supply pad; and
a sixth pad connecting line connecting a respective second row connecting structure in the second row of connecting structures with the at least one second voltage supply pad.

17. The display substrate of claim 11, further comprising:
at least one second voltage supply pad in a peripheral area of the display substrate;
a second corner connecting structure directly adjacent to, and connected to, the at least one second voltage supply pad;
a seventh pad connecting line connecting the second corner connecting structure with the at least one second voltage supply pad; and
an eighth pad connecting line connecting the second corner connecting structure with the at least one second voltage supply pad.

18. The display substrate of claim 11, further comprising at least one first voltage supply pad in a peripheral area of the display substrate;
wherein the at least one first voltage supply pad substantially surrounds the display area; and
the first voltage supply network is connected to the at least one first voltage supply pad on all sides of the display area.

19. The display substrate of claim 11, further comprising at least one second voltage supply pad in a peripheral area of the display substrate
wherein the at least one second voltage supply pad comprises two portions on two opposite sides of the display area, the two portions configured to receive a second voltage supply signal;
the second voltage supply network is connected to the two portions of the at least one second voltage supply pad on two opposite sides of the display area.

20. A display apparatus, comprising the display substrate of claim 1, and one or more integrated circuits connected to the display substrate.
